(19) United States
(12) Patent Application Publication
(10) Pub. No.: US 2024/0397804 A1
(43) Pub. Date: Nov. 28, 2024

(54) COLOR CONVERSION SUBSTRATE AND DISPLAY DEVICE INCLUDING THE SAME

(71) Applicant: Samsung Display Co., Ltd., Yongin-Si (KR)

(72) Inventors: KEUNWOO PARK, Yongin-si (KR); TAEHOON KIM, Yongin-si (KR); DANBI YANG, Yongin-si (KR); GAK SEOK LEE, Yongin-si (KR); KANGSEOB JEONG, Yongin-si (KR)

(21) Appl. No.: 18/422,984

(22) Filed: Jan. 25, 2024

(30) Foreign Application Priority Data
May 24, 2023 (KR) 10-2023-0066640

(51) Int. Cl. H10K 59/80; H10K 59/38

(52) U.S. Cl. CPC H10K 59/8792; H10K 59/38

(57) ABSTRACT

A color conversion substrate includes a substrate including a first transparent area and a second transparent area, a color filter layer disposed on the substrate, a light-blocking layer disposed on the color filter layer and defining the first transparent area and the second transparent area, a first organic structure in the first transparent area and including a scattering particle, a first color conversion part in the first transparent area covering the first organic structure, the first color conversion part including a first color conversion particle, and a transparent part in the second transparent area and including the scattering particle.

### CROSS-REFERENCE TO RELATED APPLICATION(S)

The present application claims priority to and the benefit of Korean Patent Application No. 10-2023-0066640 filed on May 24, 2023 in the Korean Intellectual Property Office (KIPO), the entire disclosure of which is incorporated herein by reference.

### BACKGROUND

### 1. Field

Embodiments relate to a display device. More particularly, embodiments relate to a color conversion substrate and a display device including the color conversion substrate.

### 2. Description of the Related Art

A display device is a device that displays images to provide visual information to users. The display device may include a color conversion substrate including a color conversion layer and a color filter layer, and an array substrate including a plurality of pixels.

A sealing member and a filling layer may be disposed between the color conversion substrate and the array substrate. The sealing member may couple the color conversion substrate and the array substrate, and the filling layer may fill a gap between the color conversion substrate and the array substrate.

### SUMMARY

This disclosure provides a color conversion substrate with improved light efficiency.

This disclosure provides a display device including the color conversion substrate with improved light efficiency.

A color conversion substrate according to an embodiment of the disclosure includes a substrate including a first transparent area and a second transparent area; a color filter layer disposed on the substrate; a light-blocking layer disposed on the color filter layer and defining the first transparent area and the second transparent area; a first organic structure in the first transparent area and including a scattering particle; a first color conversion part in the first transparent area covering the first organic structure, the first color conversion part including a first color conversion particle; and a transparent part in the second transparent area and including the scattering particle.

In an embodiment, the scattering particle may be absent in the first color conversion layer.

In an embodiment, the first color conversion layer may have a first height, and the first organic structure may have a second height that is different from the first height.

In an embodiment, the first height may be greater than the second height.

In an embodiment, the height of the transparent part is equal to the height of the first organic structure.

In an embodiment, the first organic structure may be one of a plurality of first organic structures in the first transparent area, the first organic structures having a same height.

In an embodiment, the first organic structure is one of a plurality of first organic structures in the first transparent area, the first organic structures having different heights.

In an embodiment, the transparent part may be one of a plurality of transparent parts in the second transparent area, the transparent parts having a height smaller than a height of the light-blocking layer.

In an embodiment, the transparent part may include a same material as the first organic structure.

In an embodiment, the transparent part and the first organic structure may include a light-transmitting organic material.

A display device according to an embodiment of the disclosure includes a first base substrate including a first transparent area and a second transparent area; a color filter layer disposed on the first base substrate; a light-blocking layer disposed on the color filter layer and defining the first transparent area and the second transparent area; a first organic structure in the first transparent area and including a scattering particle; a first color conversion part in the first transparent area covering the first organic structure, the first color conversion part including a first color conversion particle; a transparent part in the second transparent area and including the scattering particle; a second base substrate coupled to the first base substrate; a display device layer disposed on the second base substrate; and a filling layer disposed between the display device layer and the light-blocking layer.

In an embodiment, the scattering particle is absent in the first color conversion layer.

In an embodiment, the first color conversion layer may have a first height, and the first organic structure may have a second height that is different from the first height.

In an embodiment, the first height may be greater than the second height.

In an embodiment, the transparent part may have the second height.

In an embodiment, the first organic structure may be one of a plurality of first organic structures in the first transparent area that have the same height.

In an embodiment, the first organic structure may be one of a plurality of first organic structures in the first transparent area, the plurality of organic structures having different heights.

In an embodiment, the transparent part may be one of a plurality of transparent parts that have a height smaller than a height of the light-blocking layer.

In an embodiment, the transparent part may include a same material as the first organic structure.

In an embodiment, the transparent part and the first organic structure may include a light-transmitting organic material.

The color conversion substrate and the display device including the color conversion substrate according to embodiments of the disclosure may include the first organic structure in the first transparent area that includes the scattering particle. Accordingly, the color conversion substrate and the display device may reduce an external light reflection area and improve black display quality.

In addition, the color conversion substrate and the display device may include the first color conversion part in the first transparent area, includes the first color conversion particle, and covers the first organic structure. Accordingly, the color conversion substrate and the display device may increase probability of a reaction between an incident light and the first color conversion particle by increasing an optical path of the incident light, thereby improving light efficiency.

### BRIEF DESCRIPTION OF THE DRAWINGS

FIG. 1 is a plan view illustrating a display device.

FIG. 2 is a cross-sectional view taken along line I-I′ of FIG. 1.

FIG. 3 is an enlarged view of area A of FIG. 1.

FIG. 4 is a cross-sectional view taken along line II-II′ of FIG. 3.

FIG. 5 is an enlarged view of a first organic structure included in a color conversion substrate of FIG. 3.

FIG. 6 is a cross-sectional view illustrating an array substrate including the display device of FIG. 4.

FIGS. 7 and 8 are views illustrating a light-emitting layer included in the display device of FIG. 6.

FIGS. 9, 10, 11, 12, 13, 14, 15, and 16 are views illustrating a manufacturing method of the display device of FIG. 1.

FIG. 17 is an enlarged view illustrating a color conversion substrate.

FIG. 18 is a cross-sectional view illustrating the display device including the color conversion substrate of FIG. 17.

FIG. 19 is an enlarged view of the first organic structure included in the display device of FIG. 18.

FIGS. 20, 21, 22, and 23 are views illustrating a manufacturing method of the display device of FIG. 18.

FIG. 24 is an enlarged view illustrating a color conversion substrate.

FIG. 25 is a view illustrating a display device including the color conversion substrate of FIG. 24.

FIGS. 26, 27, 28, and 29 are views illustrating a manufacturing method of the display device of FIG. 25.

### DETAILED DESCRIPTION OF THE EMBODIMENTS

Hereinafter, embodiments will be described in more detail with reference to the accompanying drawings. The same reference numerals are used for the same components in the drawings, and redundant descriptions of the same components will be omitted.

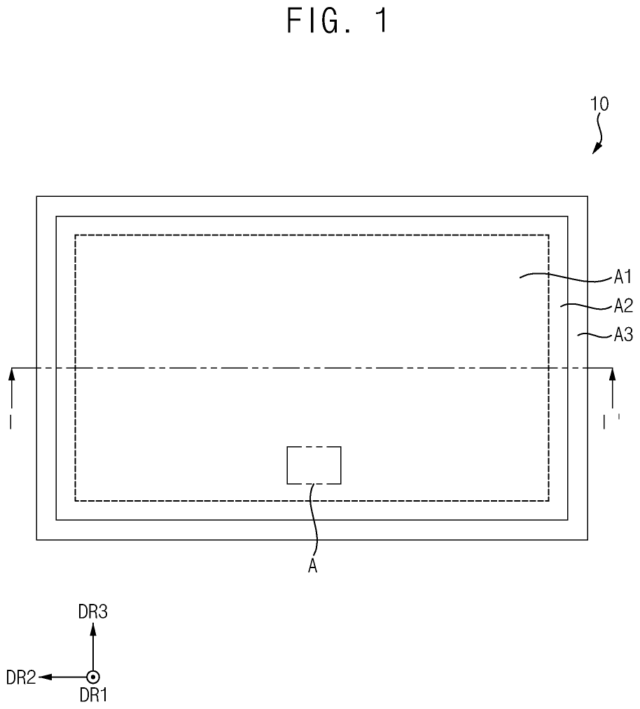

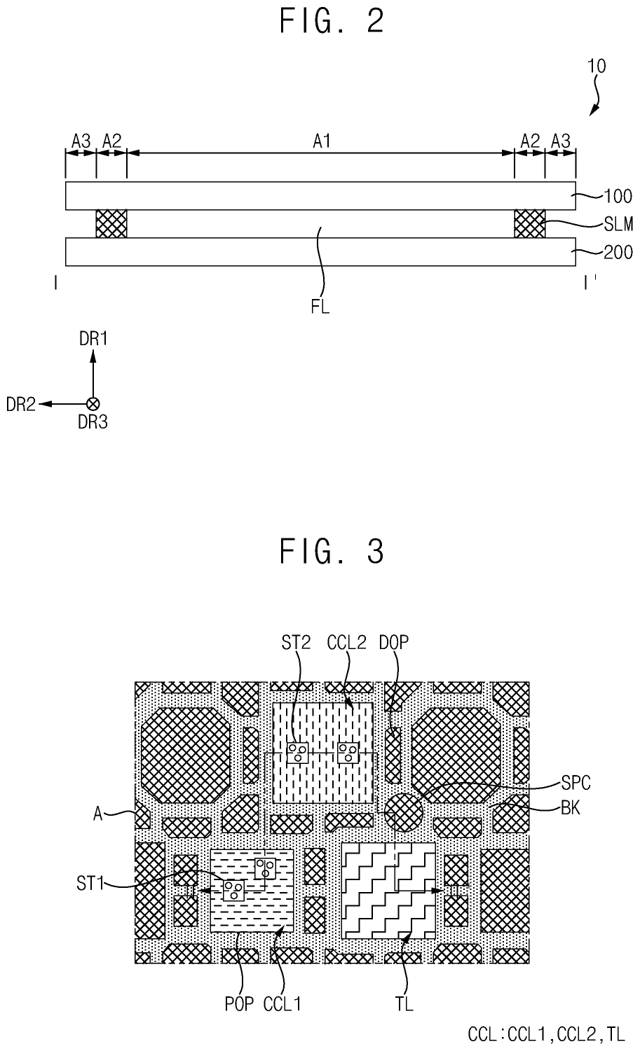

FIG. 1 is a plan view illustrating a display device. FIG. 2 is a cross-sectional view taken along line I-I′ of FIG. 1.

Referring to FIG. 1, a display device 10 may include a first area A1, a second area A2, and a third area A3 in a plan view.

For example, the plane may be defined by a second direction DR2 and a third direction DR3. Each of the second direction DR2 and the third direction DR3 may be non-parallel to a first direction DR1. As used herein, the direction of the arrow is the “positive” direction in that axis. The direction opposite the direction of the arrow is the “negative” direction in that axis.

The second area A2 and the third area A3 may surround the first area A1. Specifically, the second area A2 may surround the first area A1 in the plan view. The third area A3 may surround the second area A2 in the plan view.

The first area A1 may be a display area where the image is displayed. The second area A2 and the third area A3 may be non-display areas where the images are not displayed. Specifically, the second area A2 may be a sealing area. The sealing area may be an area where a sealing member SLM is disposed. The third area A3 may be an outer area. The outer area may be an area where circuit structures (e.g., various wires, driving circuits, or the like) are placed.

Referring to FIGS. 1 and 2, the display device 10 may include a color conversion substrate 100, the sealing member SLM, and an array substrate 200 in a cross-sectional view. For example, the cross-section may be defined by the first direction DR1 and the second direction DR2.

The color conversion substrate 100 and the array substrate 200 may face each other. For example, the color conversion substrate 100 and the array substrate 200 may face each other in the first direction DR1.

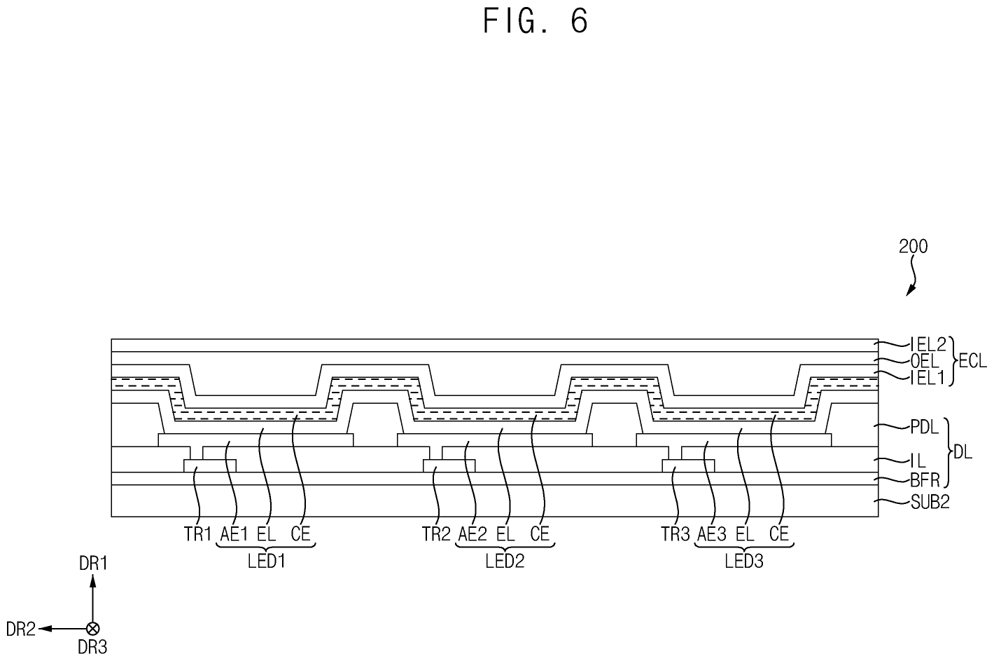

The array substrate 200 may include a plurality of pixels. For example, the plurality of pixels may be arranged in the first area A1. Each of the plurality of pixels may include a light-emitting device (e.g., a first light-emitting diode LED1, a second light-emitting diode LED2, and a third light-emitting diode LED3 of FIG. 6). For example, the light-emitting device may be an inorganic light-emitting device, an organic light-emitting device, or the like. The light-emitting device may generate light according to a driving signal.

The color conversion substrate 100 may include a color conversion layer (e.g., a color conversion layer CCL of FIG. 3). For example, the color conversion layer may be disposed in the first area A1. The color conversion layer may include a color conversion particle. For example, the color conversion particle may be a red quantum dot, a green quantum dot, a blue quantum dot, or the like. The color conversion particle may convert a wavelength of the light generated by the light-emitting device.

For example, the color conversion particle may have a core-shell structure. For example, the core may include II-VI (InP, InGaP, GaP, or the like), I-VII (CdS, CdSe, CdSeS, CdTe, ZnS, ZnSe, ZnSeS, ZnTe, ZnSeTe, or the like), I-III-VI (CuInS, CuInSe, CuGaS, CuGaSe, CuInGaS, CuInGaSe, AgInGaS, AgInGaSe, AgInS, AgInSe, AgGaS, AgGaSe, or the like), Perovskite structure (CsPbCl, CsPb(ClBr), CsPbBr, CsPb(BrI), CsPbI, Cs(SnPb)Cl, Cs(SnPb)(ClBr), Cs(SnPb)Br, Cs(SnPb)(BrI), Cs(SnPb)I, CsSnCl, CsSn(ClBr), CsSnBr, CsSn(BrI), CsSnI, or the like). These may be used alone or in combination with each other. The shell may include ZnS, ZnSe, ZnSeS, AgGaInS, AgGaS, AgInS, GaS, CdSe, CdS, or the like. These may be used alone or in combination with each other. However, the disclosure is not limited thereto.

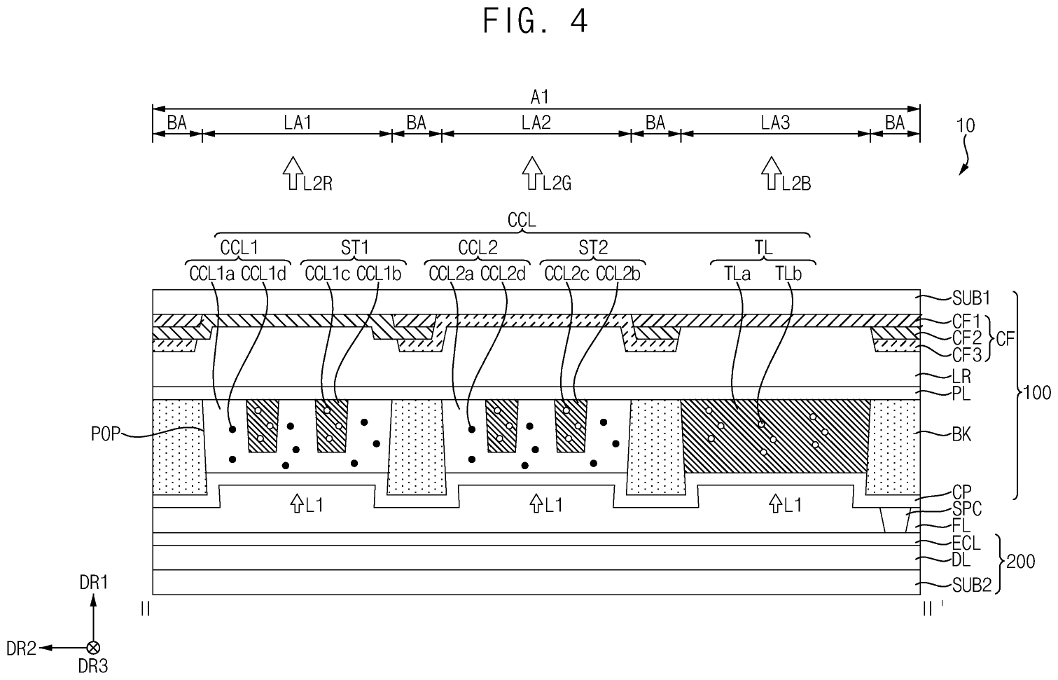

The color conversion substrate 100 may further include a color filter layer (e.g., a color filter layer CF of FIG. 4). For example, the color filter layer may be disposed in the first area A1. In this case, the color filter layer may transmit light having a specific wavelength. For example, the color filter layer may be disposed in the second area A2 and the third area A3. The color filter layer may prevent the circuit structure from being visible from outside the display device 10. In addition, the color filter layer may prevent light leakage phenomenon. The light leakage phenomenon may refer to a phenomenon in which light reflected from the circuit structure, light emitted from the first area A1, or the like is emitted through the second area A2 and the third area A3.

The sealing member SLM may be disposed between the array substrate 200 and the color conversion substrate 100 in the cross-sectional view. For example, the sealing member SLM may be disposed in the second area A2. Accordingly, the sealing member SLM may couple the array substrate 200 and the color conversion substrate 100.

A filling layer FL may be disposed between the array substrate 200 and the color conversion substrate 100. For example, the filling layer FL may be disposed in the first area A1. The filling layer FL may maintain a gap between the array substrate 200 and the color conversion substrate 100. Accordingly, the filling layer FL may act as a buffer against external pressure applied to the display device 10. For example, the filling layer FL may include polyimide, acrylate, or the like. However, the disclosure is not limited thereto. For example, the filling layer FL may have an air gap structure.

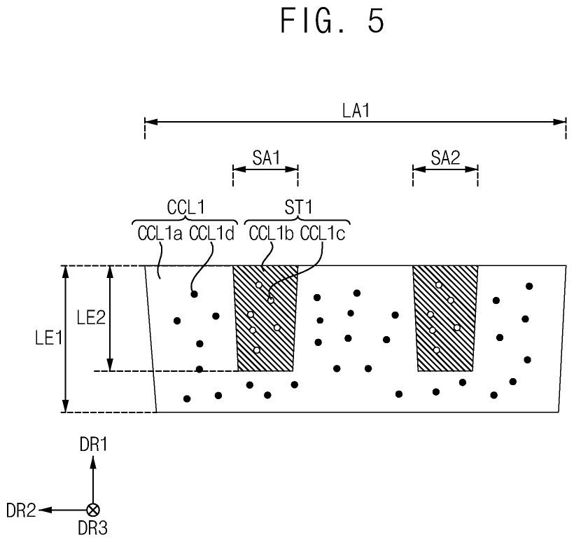

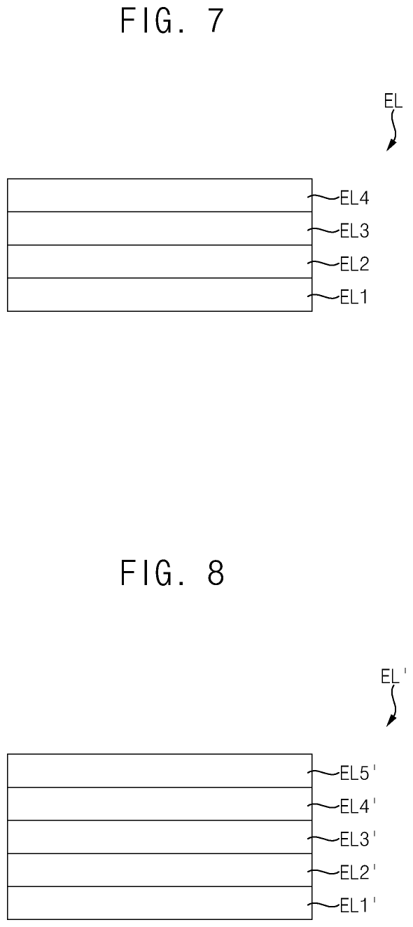

FIG. 3 is an enlarged view of area A of FIG. 1. FIG. 4 is a cross-sectional view taken along line II-II′ of FIG. 3. FIG. 5 is an enlarged view of a first organic structure included in a color conversion substrate of FIG. 3. FIG. 6 is a cross-sectional view illustrating an array substrate including the display device of FIG. 4. FIGS. 7 and 8 are views illustrating a light-emitting layer included in the display device of FIG. 6.

Referring to FIGS. 3 and 4, as described above, the display device 10 may include the color conversion substrate 100, the array substrate 200, and the filling layer FL. In an embodiment, the color conversion substrate 100 may include a first base substrate SUB1, the color filter layer CF, a low refractive layer LR, a protective layer PL, a light-blocking layer BK, the color conversion layer CCL, a capping layer CP, and a spacer SPC. The array substrate 200 may include a second base substrate SUB2, a display device layer DL, and an encapsulation layer ECL.

Light generated in the array substrate 200 (i.e., incident light L1) may be incident on the color conversion substrate 100. For example, the incident light L1 may be blue light. However, the disclosure is not limited thereto. For example, the incident light L1 may be light of various colors. For example, the incident light L1 may be white light.

For example, the first area A1 may include a light-emitting area and a light-blocking area BA. Specifically, the light-emitting area may include a first transparent area LA1, a second transparent area LA2, and a third transparent area LA3. The first transparent area LA1, the second transparent area LA2, and the third transparent area LA3 may be spaced apart from each other in the plan view and may be repeatedly arranged. However, the disclosure is not limited thereto. The light-emitting area may include two or four or more types of transparent areas.

The incident light L1 that passes through the color conversion substrate 100 may be emitted to the outside of the display device 10. In the first transparent area LA1, the first transmitted light L2R may be emitted as red light. In the second transparent area LA2, the second transmitted light L2G may be emitted as green light. In the third transparent area LA3, the third transmitted light L2B may be emitted as blue light. However, the disclosure is not limited thereto. For example, the first transmitted light L2R, the second transmitted light L2G, and the third transmitted light L2B may be light of different colors.

The light-blocking area BA may surround the first transparent area LA1, the second transparent area LA2, and the third transparent area LA3 in the plan view. For example, the light-blocking area BA may have a grid shape in the plan view. However, the disclosure is not limited thereto. For example, the light-blocking area BA may have various planar shapes.

In an embodiment, as the display device 10 includes the first area A1, the second area A2, and the third area A3, the first base substrate SUB1 may also include the first area A1, the second area A2, and the third area A3. As described above, the first area A1 may include the light-emitting area (e.g., the first transparent area LA1, the second transparent area LA2, and the third transparent area LA3) and the light-blocking area BA surrounding the light-emitting area.

The first base substrate SUB1 may include a transparent insulating material. For example, the first base substrate SUB1 may include glass, plastic, or the like.

In an embodiment, the color filter layer CF may be disposed on the first base substrate SUB1 (e.g., in a negative direction in the first direction DR1).

The color filter layer CF may include a plurality of color filter patterns. For example, the color filter layer CF may include a first color filter pattern CF1, a second color filter pattern CF2, and a third color filter pattern CF3.

Each of the plurality of color filter patterns may overlap the light-emitting area. For example, the first color filter pattern CF1 may overlap the third transparent area LA3. Accordingly, the first color filter pattern CF1 may selectively transmit blue light. The second color filter pattern CF2 may overlap the first transparent area LA1. Accordingly, the second color filter pattern CF2 may selectively transmit red light. The third color filter pattern CF3 may overlap the second transparent area LA2. Accordingly, the third color filter pattern CF3 may selectively transmit green light. The color filter layer CF may selectively transmit only light of a specific wavelength and emit various colored lights to the outside of the display device 10.

Each of the plurality of color filter patterns may also overlap the light-blocking area BA. For example, the first color filter pattern CF1 may overlap the third transparent area LA3 and the light-blocking area BA, and the first color filter pattern CF1 might not overlap with the first transparent area LA1 and the second transparent area LA2. The second color filter pattern CF2 may overlap the first transparent area LA1 and the light-blocking area BA, and second color filter pattern CF2 might not overlap the second transparent area LA2 and the third transparent area LA3. The third color filter pattern CF3 may overlap the second transparent area LA2 and the light-blocking area BA, and third color filter pattern CF3 might not overlap the first transparent area LA1 and the third transparent area LA3. In other words, in the light-blocking area BA, a portion of the first color filter pattern CF1, a portion of the second color filter pattern CF2, and a portion of the third color filter pattern CF3 may overlap each other. Accordingly, the color filter layer CF may prevent color mixing from occurring between the adjacent first, second, and third transparent areas LA1, LA2, and LA3.

Each of the plurality of color filter patterns may overlap the second area A2 and the third area A3. In this case, a portion of the color filter layer CF that overlaps the second area A2 and the third area A3 may serve as a light-blocking member. In the second area A2 and the third area A3, the third color filter pattern CF3, the second color filter pattern CF2, and the first color filter pattern CF1 may be disposed to overlap one another in the first direction DR1 in the second area A2 and the third area A3. Accordingly, the color filter layer CF may effectively block light traveling in the first direction DR1 in the second area A2 and the third area A3. Accordingly, the color filter layer CF may prevent the light leakage phenomenon from occurring in the display device 10.

However, the disclosure is not limited thereto. For example, the color filter layer CF may be disposed only in the first area A1, and an additional light-blocking member may be disposed in the second area A2 and the third area A3.

Additionally, in FIG. 4, the second color filter pattern CF2 may be disposed on the first color filter pattern CF1 (e.g., in the negative direction along the first direction DR1), and the third color filter pattern CF3 may be disposed on the second filter pattern CF2. However, an overlapping position of the color filter layer CF, overlapping area of the color filter layer CF, overlapping order of the color filter layer CF, or the like may be changed without departing from the scope of this disclosure.

The low refractive layer LR may be disposed on the color filter layer CF.

For example, the low refractive layer LR may include a material having a relatively smaller refractive index than a material included in the color conversion layer CCL. The material may be organic. The low refractive layer LR may improve light extraction efficiency. Accordingly, luminance and lifespan of the display device 10 may be increased. However, the disclosure is not limited thereto. For example, the low refractive layer LR may include an inorganic material. Alternatively, the low refractive layer LR may be omitted.

The protective layer PL may be disposed on the low refractive layer LR. For example, the protective layer PL may cover the low refractive layer LR. For example, the protective layer PL may include an inorganic material. However, the disclosure is not limited thereto. For example, the protective layer PL may include an organic material. Alternatively, the protective layer PL may be omitted.

In an embodiment, the light-blocking layer BK may be disposed on the color filter layer CF. Specifically, the light-blocking layer BK may be disposed on the protective layer PL.

The light-blocking layer BK may include a light-blocking material. For example, the light-blocking layer BK may include an organic material. Specifically, the organic material may include black pigment, dye, carbon black, or the like. These may be used alone or in combination with each other. However, the disclosure is not limited thereto. The light-blocking layer BK may include an inorganic material.

The light-blocking layer BK may be disposed in the first area A1. For example, the light-blocking layer BK may define the light-emitting area. In an embodiment, the light-blocking layer BK may define the first transparent area LA1, the second transparent area LA2, and the third transparent area LA3. To this end, the light-blocking layer BK might not overlap the light-emitting area (e.g., the first transparent area LA1, the second transparent area LA2, and the third transparent area LA3), and the light-blocking layer BK may entirely overlap with the light-blocking area BA. The light-blocking layer BK may have a grid shape in the plan view.

A plurality of openings may be defined in the light-blocking layer BK. For example, a pixel opening POP and a dummy opening DOP may be defined in the light-blocking layer BK (see FIG. 3).

The pixel opening POP may have various planar shapes. For example, the pixel opening POP may have a planar shape such as a circle, triangle, square, pentagon, hexagon, heptagon, octagon, or the like.

The dummy opening DOP may be adjacent to the pixel opening POP. For example, the dummy opening DOP may surround the pixel opening POP in the plan view. The dummy opening DOP may accommodate ink that is mistakenly deposited in a process of forming a first color conversion part CCL1 or a second color conversion part CCL2, which will be described later.

The color conversion layer CCL may be disposed on the protective layer PL. Specifically, the color conversion layer CCL may be disposed in the pixel opening POP of the light-blocking layer BK in the first area A1. The color conversion layer CCL may convert the color of the incident light L1.

In an embodiment, the color conversion layer CCL may include a plurality of color conversion parts spaced apart from each other. For example, the color conversion layer CCL may include the first color conversion part CCL1, the second color conversion part CCL2, and a transparent part TL.

In an embodiment, the color conversion layer CCL may include a first organic structure ST1, the first color conversion part CCL1, a second organic structure ST2, the second color conversion part CCL2, and the transparent part TL.

In an embodiment, the first organic structure ST1 may overlap the first transparent area LA1 and may include a first scattering particle CCL1c and an organic dispersion part CCL1b. The first scattering particle CCL1c may be dispersed in the organic dispersion part CCL1b.

The first scattering particle CCL1c may increase the optical path by scattering the incident light L1 without substantially changing the wavelength of the incident light L1. For example, the first scattering particle CCL1c may include metal oxide, organic material, or the like. For example, the first scattering particle CCL1c may include TiO₂, SiO₂, BaSO₄, ZnO, Al₂O₃, CaCO₃, or the like. These may be used alone or in combination with each other. However, the disclosure is not limited thereto.

In an embodiment, the organic dispersion part CCL1b may include a light-transmitting organic material. The light-transmitting organic material may be a material that may transmit all wavelengths of visible light. For example, the organic material may be a photoresist. In this case, the first organic structure ST1 may be formed through a photolithography process. However, the disclosure is not limited thereto.

In an embodiment, the first color conversion part CCL1 may overlap the first

transparent area LA1 and may include a first color conversion particle CCL1d and a first dispersion part CCL1a. The first color conversion particle CCL1d may be dispersed in the first dispersion part CCL1a.

The first color conversion particle CCL1d may include various particles that convert the color of the incident light L1. The first color conversion particle CCL1d may include a quantum dot that absorbs the incident light L1 and emits the red light. However, the disclosure is not limited thereto.

The quantum dot may be defined as a semiconductor material having nanocrystals. The quantum dot may have a specific band gap depending on their composition and size. Accordingly, the quantum dot may convert the incident light L1 into light having a different wavelength from the incident light L1. For example, the quantum dot may have a diameter of about 100 nanometers (nm) or less. Specifically, the quantum dot may have a diameter of about 1 nm to about 20 nm.

The first dispersion part CCL1a may include resin. For example, the first dispersion part CCL1a may include epoxy resin, acrylic resin, phenol resin, melamine resin, cardo resin, imide resin, or the like. These may be used alone or in combination with each other. In this case, the first dispersion part CCL1a may be formed through an inkjet process. However, the disclosure is not limited thereto.

The first color conversion part CCL1 may convert the incident light L1 into the red first transmitted light L2R. The incident light L1 that is not converted by the first color conversion part CCL1 may be blocked (e.g., absorbed or reflected) by the second color filter pattern CF2. Accordingly, in the first transparent area LA1, the red first transmitted light L2R passes through the first base substrate SUB1 and travels outside of the display device 10 (e.g., the first direction DR1).

In an embodiment, the first color conversion part CCL1 may cover the first organic structure ST1. To this end, the first organic structure ST1 may be first formed in the pixel opening POP overlapping the first transparent area LA1 and defined by the light-blocking layer BK, and then the first color conversion part CCL1 may be formed to cover the first organic structure ST1.

Referring to FIG. 5, in an embodiment, the first color conversion part CCL1 may have a first height LE1 and the first organic structure ST1 may have a second height LE2. The first height LE1 may be greater than the second height LE2. The height may mean a length in the first direction DR1. As the optical path of the incident light L1 becomes longer by the length obtained by subtracting the second height LE2 from the first height LE1, the probability of reaction between the incident light L1 and the first color conversion particle CCL1d may be greater.

In an embodiment, the first scattering particle CCL1c may be disposed only in the first organic structure ST1, and the first color conversion particle CCL1d may be disposed only in the first dispersion part CCL1a. In other words, the first scattering particle CCL1c might not be disposed in the first dispersion part CCL1a.

To this end, the first organic structure ST1 may be formed of the organic dispersion part CCL1b including the first scattering particle CCL1c using the photolithography process. The first color conversion part CCL1 may be formed of the first dispersion part CCL1a including the first color conversion particle CCL1d using the inkjet process.

In other words, as the display device 10 includes the first organic structure ST1, a space in which the first scattering particle CCL1c is disposed may be limited (or reduced).

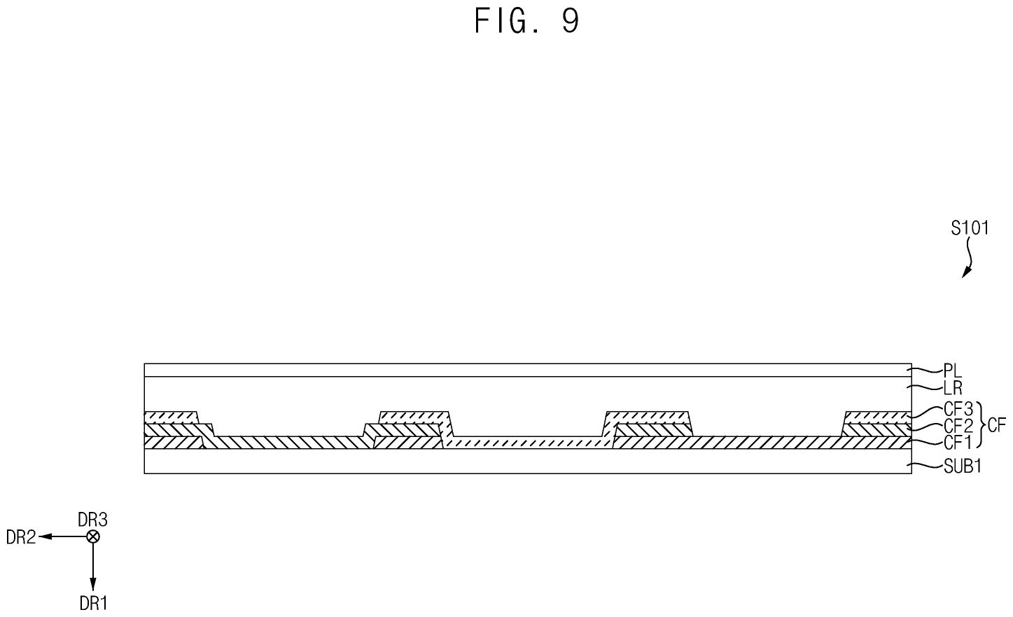

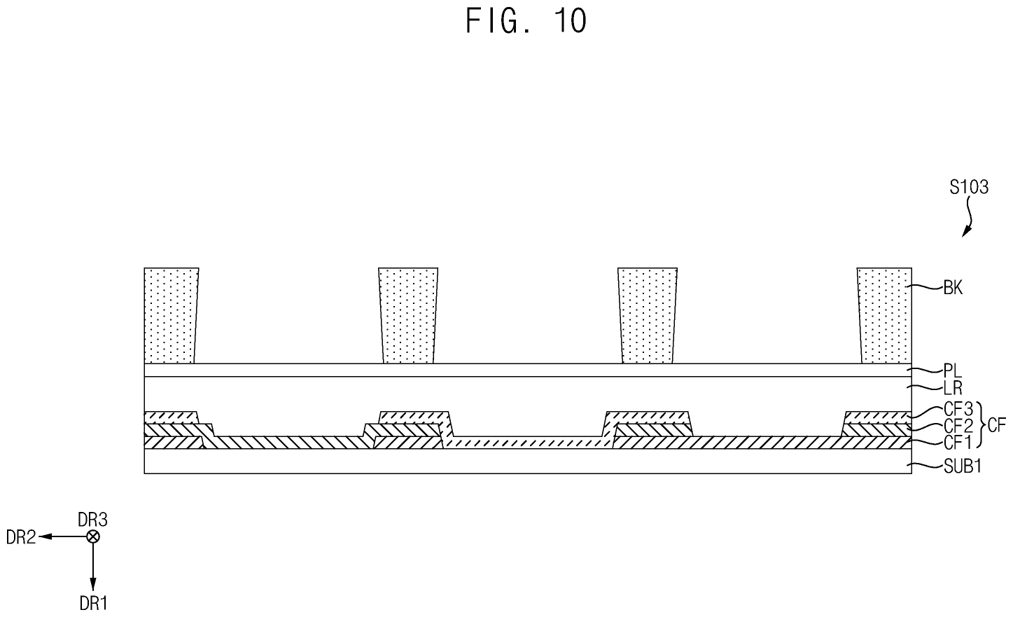

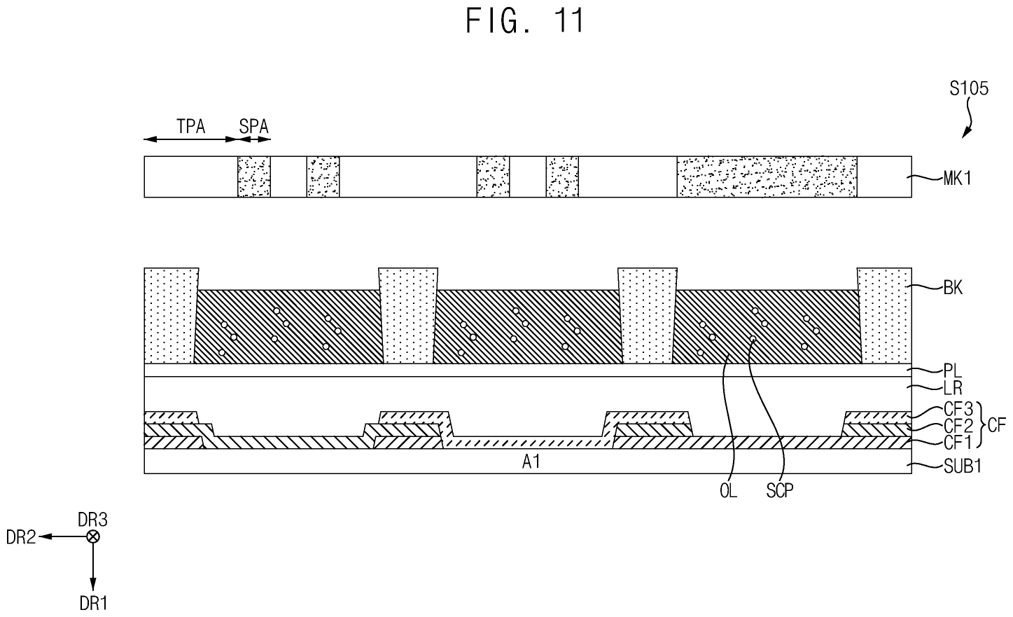

In an embodiment, the first organic structure ST1 may include a first sub-organic structure and a second sub-organic structure. The first sub-organic structure may be located in a first arrangement area SA1, and the second sub-organic structure may be located in a second arrangement area SA2. Accordingly, the space in which the first scattering particle CCL1c is disposed may be limited to the first arrangement area SAI and the second arrangement area SA2. A detailed description of the method of forming the color conversion layer CCL will be described later with reference to FIGS. 9, 10, 11, 12, 13, 14, 15, and 16.

Referring again to FIGS. 1, 2, 3, and 4, in an embodiment, the second organic structure ST2 may be in the second transparent area LA2, and may include a second scattering particle CCL2c and an organic dispersion part CCL2b. The second scattering particle CCL2c may be dispersed and arranged within the organic dispersion part CCL2b. The organic dispersion part CCL2b may be substantially the same as or similar to the organic dispersion part CCL1b included in the first organic structure ST1. Additionally, the second scattering particle CCL2c may be substantially the same as or similar to the first scattering particle CCL1c. Hereinafter, descriptions of structures that are similar to the first organic structure ST1 will be omitted for simplicity.

In an embodiment, the second color conversion part CCL2 may be in the second transparent area LA2 and include a second color conversion particle CCL2d and a second dispersion part CCL2a. The second color conversion particle CCL2d may be dispersed and arranged within the second dispersion part CCL2a. The second dispersion part CCL2a may be substantially a same as or similar to the first dispersion part CCL1a. Hereinafter, descriptions of structures that are similar to the first color conversion part CCL1 will be omitted for simplicity.

The second color conversion particle CCL2d may include various particles that change the color of the incident light L1. The second color conversion particle CCL2d may include a quantum dot that absorbs the incident light L1 and emits green light. However, the disclosure is not limited thereto.

The second color conversion part CCL2 may convert the incident light L1 into the green second transmitted light L2G. The incident light L1 that is not converted by the second color conversion part CCL2 may be blocked (e.g., absorbed or reflected) by the third color filter pattern CF3. Accordingly, in the second transparent area LA2, the green second transmitted light L2G may pass through the first base substrate SUB1 and travel outside of the display device 10.

In an embodiment, the second color conversion part CCL2 may cover the second organic structure ST2. To this end, the second organic structure ST2 may be first formed in the pixel opening POP overlapping the second transparent area LA2 and defined by the light-blocking layer BK, and then the second color conversion part CCL2 may be formed to cover the second organic structure ST2.

In an embodiment, the second scattering particle CCL2c may be disposed in the second organic structure ST2 but not in the second color conversion part CCL2, and the second color conversion particle CCL2d may be disposed in the second dispersion part CCL2a but not in the second organic structure ST2. In other words, the second scattering particle CCL2c may not be disposed in the second dispersion part CCL2a. To this end, the second organic structure ST2 may be formed of the organic dispersion part CCL2b including the second scattering particle CCL2c using the photolithography process. The second color conversion part CCL2 may be formed of the second dispersion part CCL2a including the second color conversion particle CCL2d using the inkjet process. In other words, as the display device 10 includes the second organic structure ST2, the space in which the second scattering particle CCL2c is disposed may be limited (or reduced).

In an embodiment, the transparent part TL may overlap the third transparent area LA3 and may include a third scattering particle TLb and an organic dispersion layer TLa. The third scattering particle TLb may be dispersed in the organic dispersion layer TLa. The third scattering particle TLb may be substantially the same as or similar to the first scattering particle CCL1c. Hereinafter, descriptions of structures that are similar to the first organic structure ST1 will be omitted for simplicity.

In an embodiment, the organic dispersion layer TLa may include a same material as the organic dispersion part CCL1b in the first organic structure ST1 and the organic dispersion part CCL2b in the second organic structure ST2. For example, the organic dispersion layer TLa included in the transparent part TL may include the light-transmitting organic material. In this case, the first organic structure ST1, the second organic structure ST2, and the transparent part TL may be formed simultaneously with the same process. Accordingly, in an embodiment, the height of the first organic structure ST1 and the transparent part TL may be the same.

The transparent part TL may transmit the incident light L1 and emit the blue third transmitted light L2B. Some wavelengths of the incident light L1 may be blocked (e.g., absorbed or reflected) by the first color filter pattern CF1. Accordingly, in the third transparent area LA3, the blue third transmitted light L2B may pass through the first base substrate SUB1 and travel outside of the display device 10.

The first transmitted light L2R of the first transparent area LA1, the second transmitted light L2G of the second transparent area LA2, and the third transmitted light L2B of the third transparent area LA3 may be combined to display the image in the first area A1.

The color conversion substrate 100 shown in FIGS. 3 and 4 is an example, and a type of scattering particle, a size of the scattering particle, a density of the scattering particle, the organic matter included in the organic dispersion layer, or the like. may be changed without departing from the scope of this disclosure.

For example, the transparent part TL may further include a third color conversion particle that absorbs the incident light L1 and emits blue light.

In addition, the organic dispersion layer TLa in the transparent part TL may include a different material from the organic dispersion part CCL1b in the first organic structure ST1 and the organic dispersion layer CCL2b in the second organic structure ST2. The third scattering particle TLb may include a different material from the first scattering particle CCL1c.

On the other hand, a concentration of the first scattering particle CCL1c, a placement density of the second scattering particle CCL2c, and a concentration of the third scattering particle TLb may be different from each other. For example, the concentration of the third scattering particle TLb may be greater than the concentration of the first scattering particle CCL1c and the concentration of the second scattering particle CCL2c. “Concentration” of particles, as used herein, refers to the number of particles per given volume.

In an embodiment, a height (e.g., the length in the first direction DR1) of the color conversion layer CCL may be smaller than a height of the light-blocking layer BK. However, the disclosure is not limited thereto. For example, the height of the color conversion layer CCL may be substantially the same as the height of the light-blocking layer BK in some embodiments.

The capping layer CP may be disposed on the light-blocking layer BK and the color conversion layer CCL. The capping layer CP may prevent foreign materials (e.g., oxygen, moisture, or the like.) from reaching the color conversion layer CCL. For example, the capping layer CP may cover the light-blocking layer BK and the color conversion layer CCL. However, the disclosure is not limited thereto. For example, the capping layer CP may be omitted in some embodiments.

The spacer SPC may be disposed on the light-blocking layer BK. Specifically, the spacer SPC may be disposed on the capping layer CP. The spacer SPC may contact the array substrate 200. Specifically, the spacer SPC may contact the display device layer DL, which will be described later. The spacer SPC may maintain a gap between the color conversion substrate 100 and the array substrate 200.

For example, the spacer SPC may include an organic material. For example, the spacer SPC may include photoresist. However, the disclosure is not limited thereto.

Referring to FIG. 6, as described above, the array substrate 200 may include the second base substrate SUB2, the display device layer DL, and the encapsulation layer ECL.

In an embodiment, the second base substrate SUB2 may face the first base substrate SUB1. For example, the second base substrate SUB2 may face the first base substrate SUB1 in the first direction DR1.

The second base substrate SUB2 may include a transparent or opaque insulating material. For example, the second base substrate SUB2 may include glass. In this case, the array substrate 200 may be a rigid display substrate. For another example, the second base substrate SUB2 may include plastic. In this case, the array substrate 200 may be a flexible display substrate.

In an embodiment, the display device layer DL may be disposed on the second base substrate SUB2. The display device layer DL may include a buffer layer BFR, first to third transistors TR1, TR2, and TR3, an insulating layer IL, a pixel defining layer PDL, and the first to third light-emitting diodes LED1, LED2, and LED3.

The buffer layer BFR may be disposed on the second base substrate SUB2. The buffer layer BFR may prevent impurities such as oxygen and moisture from diffusing into the array substrate 200. The buffer layer BFR may include an inorganic material such as a silicon compound, metal oxide, or the like. The buffer layer BFR may have a single-layer structure or a multi-layer structure including a plurality of insulating layers.

The first to third transistors TR1, TR2, and TR3 may be disposed in the first area Al on the buffer layer BFR. A channel layer of the transistor may include an oxide semiconductor, a silicon semiconductor, an organic semiconductor, or the like. For example, the oxide semiconductor may include at least one oxide from indium (In), gallium (Ga), tin (Sn), zirconium (Zr), vanadium (V), hafnium (Hf), cadmium (Cd), germanium (Ge), and chromium (Cr), titanium (Ti), and zinc (Zn). The silicon semiconductor may include amorphous silicon, polycrystalline silicon, or the like.

The insulating layer IL may cover the first to third transistors TR1, TR2, and TR3. The insulating layer IL may include a combination of an inorganic insulating layer and an organic insulating layer.

The first to third light-emitting diodes LED1, LED2, and LED3 may be disposed on the insulating layer IL. The first to third light-emitting diodes LED1, LED2, and LED3 may be connected to the first to third transistors TR1, TR2, and TR3, respectively. The first to third light-emitting diodes LED1, LED2, and LED3 may overlap the pixel opening POP and may be spaced apart from the dummy opening DOP.

For example, first to third pixel electrodes AE1, AE2, and AE3 may be disposed on the insulating layer IL. Each of the first to third pixel electrodes AE1, AE2, and AE3 may include a conductive material such as a metal, alloy, conductive metal nitride, conductive metal oxide, transparent conductive material, or the like. Each of the first to third pixel electrodes AE1, AE2, and AE3 may have a single-layer structure or a multi-layer structure including a plurality of conductive layers.

The first to third pixel electrodes AE1, AE2, and AE3 may be respectively connected to the first to third transistors TR1, TR2, and TR3 through contact holes formed in the insulating layer IL.

The pixel defining layer PDL may be disposed on the first to third pixel electrodes AE1, AE2, and AE3. The pixel defining layer PDL may include an organic material. The pixel defining layer PDL may define a pixel opening above at least a portion of each of the first to third pixel electrodes AE1, AE2, and AE3.

A light-emitting layer EL may be disposed on the first to third pixel electrodes AE1, AE2, and AE3 at the base of the pixel openings in the pixel defining layer PDL. In an embodiment, the light-emitting layer EL may extend continuously on the first area A1 across a plurality of pixels. In another embodiment, the light-emitting layer EL may be separated from the light-emitting layer of an adjacent pixel.

The light-emitting layer EL may include at least one of an organic light-emitting material and the quantum dot. In an embodiment, the light-emitting layer EL may generate blue light. However, the disclosure is not limited thereto. In another embodiment, the light-emitting layer EL may generate the red light or the green light, or light having different colors depending on the pixel.

For example, the light-emitting layer EL may include an organic material for emitting blue light. At this time, the light-emitting layer EL may be formed as a multi-layer and may have a structure in which a plurality of blue organic light-emitting layers are stacked. For example, the light-emitting layer EL may have a structure in which three blue organic light-emitting layers are stacked.

For example, referring to FIG. 7, the light-emitting layer EL according to a first embodiment may include a first organic layer EL1, a second organic layer EL2, a third organic layer EL3, and a fourth organic layer EL4. Each of the first organic layer EL1, the second organic layer EL2, and the third organic layer EL3 may include an organic material that generates blue light, and the fourth organic layer EL4 may include an organic material that generates green light.

However, embodiments according to the disclosure are not limited thereto, and the light-emitting layer EL may have a structure in which a plurality of blue organic light-emitting layers and organic light-emitting layers that emit light of different colors are stacked.

For another example, referring to FIG. 8, the light-emitting layer EL′ according to a second embodiment may include a first organic layer EL1′, a second organic layer EL2′, a third organic layer EL3′, a fourth organic layer EL4′, and a fifth organic layer EL5′. The first organic layer EL1′ may include an organic material that generates red light, each of the second organic layer EL2′ and the fourth organic layer EL4′ may include an organic material that generates blue light, and each of the third organic layer EL3′ and the fifth organic layer EL5′ may include an organic material that generates green light.

Referring again to FIG. 6, functional layers such as a hole injection layer, a hole transport layer, an electron transport layer, and an electron injection layer may be disposed on an upper and/or lower part of the light-emitting layer EL. Alternatively, the functional layer may be omitted.

A common electrode CE may be disposed on the light-emitting layer EL. The common electrode CE may include a conductive material such as a metal, alloy, conductive metal nitride, conductive metal oxide, transparent conductive material, or the like. The common electrode CE may have a single-layer structure or a multi-layer structure including a plurality of conductive layers. In an embodiment, the common electrode CE may extend continuously on the first area A1 across the plurality of pixels.

The first pixel electrode AE1, the light-emitting layer EL, and the common electrode CE may constitute the first light-emitting diode LED1, the second pixel electrode AE2, the light-emitting layer EL, and the common electrode CE may constitute the second light-emitting diode LED2, and the third pixel electrode AE3, the light-emitting layer EL, and the common electrode CE may constitute the third light-emitting diode LED3.

The encapsulation layer ECL may be disposed on the display device layer DL. Specifically, the encapsulation layer ECL may be disposed on the common electrode CE.

The encapsulation layer ECL may cover the display device layer DL. For example, the encapsulation layer ECL may include at least one inorganic encapsulation layer and at least one organic encapsulation layer. Specifically, the encapsulation layer ECL may include a first inorganic encapsulation layer IEL1 disposed on the common electrode CE, an organic encapsulation layer OEL disposed on the first inorganic encapsulation layer IEL1, and a second inorganic encapsulation layer IEL2 disposed on the organic encapsulation layer OEL. However, the disclosure is not limited thereto. Alternatively, the encapsulation layer ECL may be omitted.

Referring again to FIGS. 2, 4, and 5, as described above, the filling layer FL may maintain the gap between the color conversion substrate 100 and the array substrate 200. In an embodiment, the filling layer FL may be disposed between the capping layer CP and the encapsulation layer ECL. For example, when the capping layer CP is omitted, the filling layer FL may be disposed between the light-blocking layer BK, the first color conversion part CCL1, the second color conversion part CCL2, the transparent part TL, and the encapsulation layers ECL. For example, when the encapsulation layer ECL is omitted, the filling layer FL may be disposed between the capping layer CP and the display device layer DL.

For example, the filling layer FL may include an organic material. For example, the organic material may include polyimide, acrylate, or the like. These may be used alone or in combination with each other. However, the disclosure is not limited thereto.

The display device according to a comparative example might not include the organic structure (e.g., the first organic structure ST1 or the second organic structure ST2). In other words, in the entire light-emitting area (e.g., the first transparent area LA1 or the second transparent area LA2), external light reflection by the scattering particle (e.g., the first scattering particle CCL1c or the second scattering particle CCL2c) may occur. The external light reflection in the entire light-emitting area may cause the display quality of black color to deteriorate.

Reducing the number of the scattering particles to prevent display quality deterioration of black color may decrease the probability of reaction between the incident light L1 and the color conversion particle (e.g., the first color conversion particle CCL1d or the second color conversion particle CCL2d). As the probability of reaction between the incident light L1 and the color conversion particle decreases, light efficiency may decrease.

On the other hand, if the number of scattering particle is increased to prevent the decrease in the light efficiency, the display quality of the black color may be further deteriorated.

The display device 10 of the disclosure may include the organic structure. As the organic structure is included, the scattering particle may be limited to an area where the organic structure is disposed (e.g., the first arrangement area SA1 or the second arrangement area SA2). In other words, the display quality of the black color may be improved by reducing the area where the external light is reflected in the light-emitting area.

In addition, as the display device 10 includes the organic structure, the optical path of the incident light L1 may increase as much as the height difference between a color conversion part (e.g., the first color conversion part CCL1 or the second color conversion part CCL2) and the organic structure. Accordingly, the probability of reaction between the incident light L1 and the color conversion particle may increase, increasing light efficiency.

In addition, as the display device 10 includes the organic structure, the first color conversion part CCL1 may further include the color conversion particles in a proportion that does not include the scattering particle. As more color conversion particles are included, the light efficiency of the display device 10 may increase.

FIGS. 9, 10, 11, 12, 13, 14, 15, and 16 are views illustrating a manufacturing method of the display device of FIG. 1. Hereinafter, descriptions that were already provided above with reference to FIGS. 1, 2, 3, 4, 5, 6, 7, and 8 will be omitted or abbreviated.

Referring to FIG. 9, the color filter layer CF may be formed on the first base substrate SUB1, the low refractive layer LR may be formed on the color filter layer CF, and the protective layer PL may be formed on the low refractive layer LR (S101).

The first base substrate SUB1 may include glass. However, the disclosure is not limited thereto.

After forming black matrices spaced apart from each other on the first base substrate SUB1, the first color filter pattern CF1, the second color filter pattern CF2, and the third color filter pattern CF3 may be formed between the black matrices. For example, the black matrices may be formed through the photolithography process. The color filter patterns (e.g., the first color filter pattern CF1, the second color filter pattern CF2, and the third color filter pattern CF3) may be formed using an inkjet printer method.

However, the disclosure is not limited thereto. For example, the color filter patterns may be formed by a spin method in which liquid is sprayed on the first base substrate SUB1 and then applied by rotating the plate, a slit method in which the color filter patterns are sprayed evenly over an entire surface through a nozzle. In this method, a color photoresist is applied and then exposed to develop the photoresist.

The low refractive layer LR and the protective layer PL may be sequentially formed on the color filter layer CF. For example, the low refractive layer LR may be formed of a material with excellent total reflection and scattering characteristics, and may be formed to be thin in consideration of light extraction efficiency. For example, the low refractive layer LR may be formed to have a thickness of about several micrometers or less. For example, the protective layer PL may be formed of a material with high strength. However, the disclosure is not limited thereto. The low refractive layer LR and the protective layer PL may be omitted.

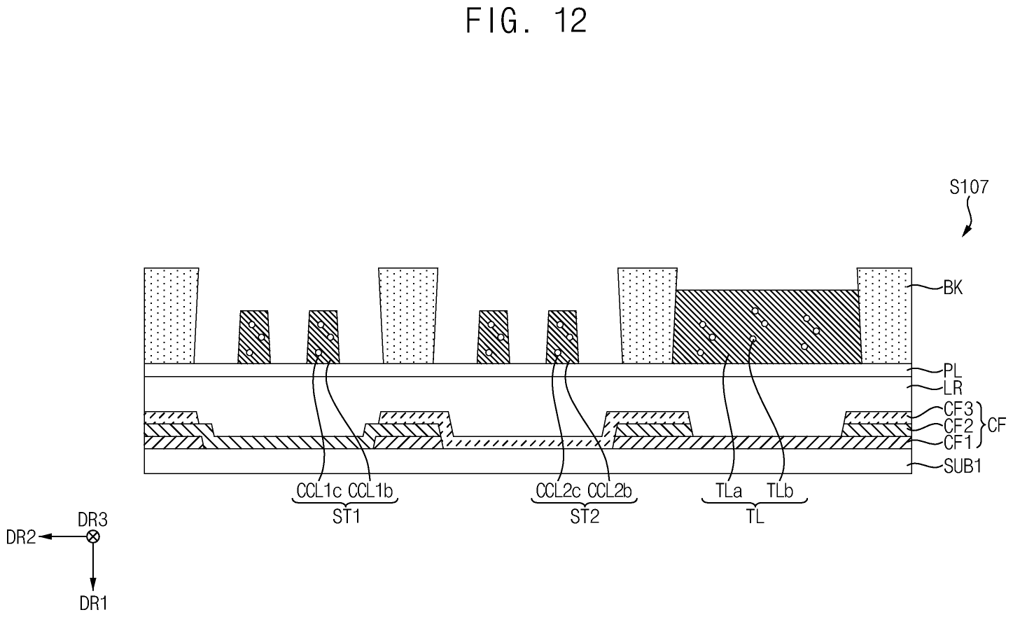

Referring to FIG. 10, the light-blocking layer BK may be formed on the color filter layer CF. Specifically, the light-blocking layer BK may be formed on the protective layer PL (S103).

The light-blocking layer BK may be formed of the light-blocking material. The light-blocking layer BK may be formed through the photolithography process. As described above with reference to FIGS. 1, 2, 3, and 4, the light-blocking layer BK may be formed to overlap only the light-blocking area (e.g., the light-blocking area BA of FIG. 4) and not the light-emitting area (e.g., the first transparent area LA1, the second transparent area LA2, and the third transparent area LA3 of FIG. 4). That is, the pixel opening (e.g., the pixel opening POP of FIG. 4) defining the light-emitting area may be formed in the light-blocking layer BK. However, the disclosure is not limited thereto.

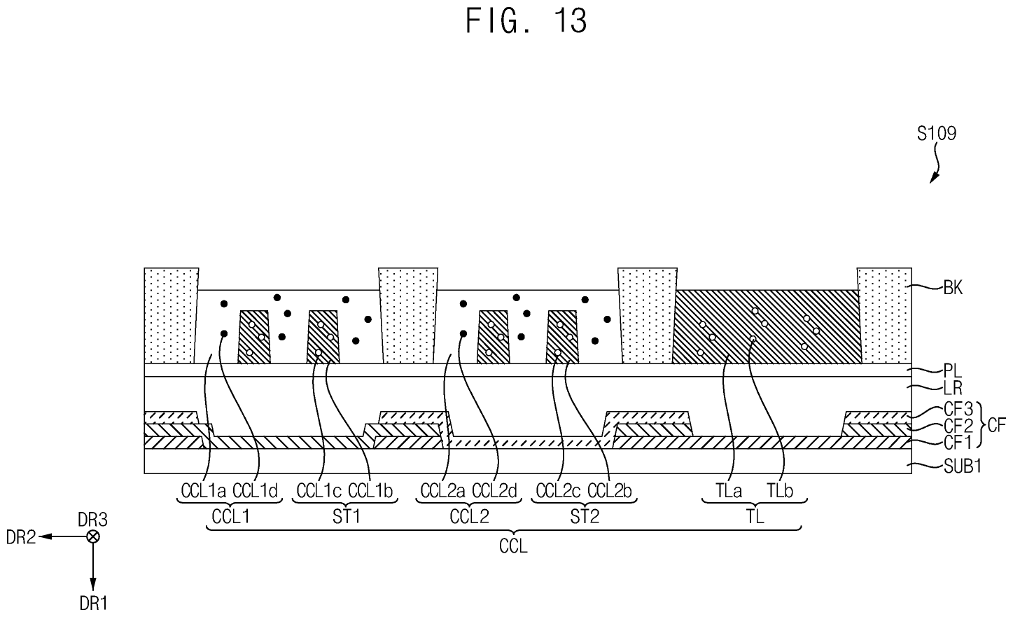

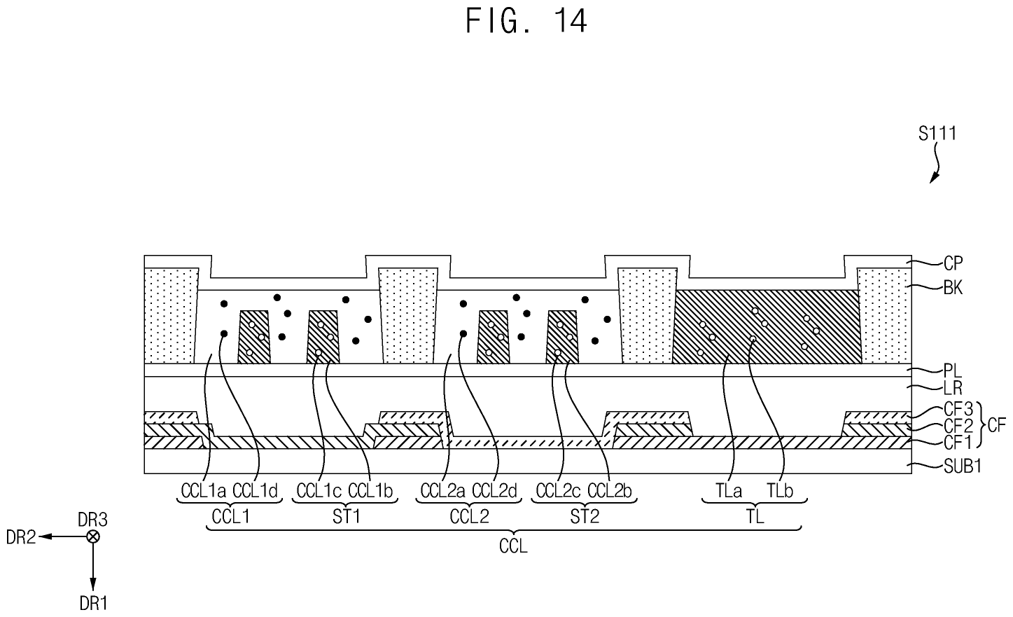

Referring to FIGS. 11 and 12, an organic material OL including a scattering particle SCP may be formed in the pixel opening formed in the light-blocking layer BK, and a mask MK1 may be disposed (S105). Next, the first organic structure ST1, the second organic structure ST2, and the transparent part TL may be formed through the exposure and development process (S107).

The organic material OL may be a photoresist. At this time, the scattering particle SCP may be mixed with the organic material OL and injected into the pixel opening. Here, the scattering particle SCP may correspond to the first scattering particle CCL1c, the second scattering particle CCL2c, and/or the third scattering particle TLb of FIG. 4.

For example, the mask MK1 may include a light transmitting part TPA and a light-blocking part SPA. The light transmitting part TPA may be a part that may transmit light, and the light-blocking part SPA may be a part that does not transmit light.

In an embodiment, the mask MK1 may be placed so that the light-blocking part SPA is formed at a location where the organic structures (e.g., the first organic structure ST1 and the second organic structure ST2) and the transparent part TL are to be formed. However, the disclosure is not limited thereto. The photoresist may be used as either a negative type or a positive type. The mask MK1 may be a halftone mask including areas with various light transmittances.

However, the disclosure is not limited thereto. The organic structure may be formed in various ways and with various materials.

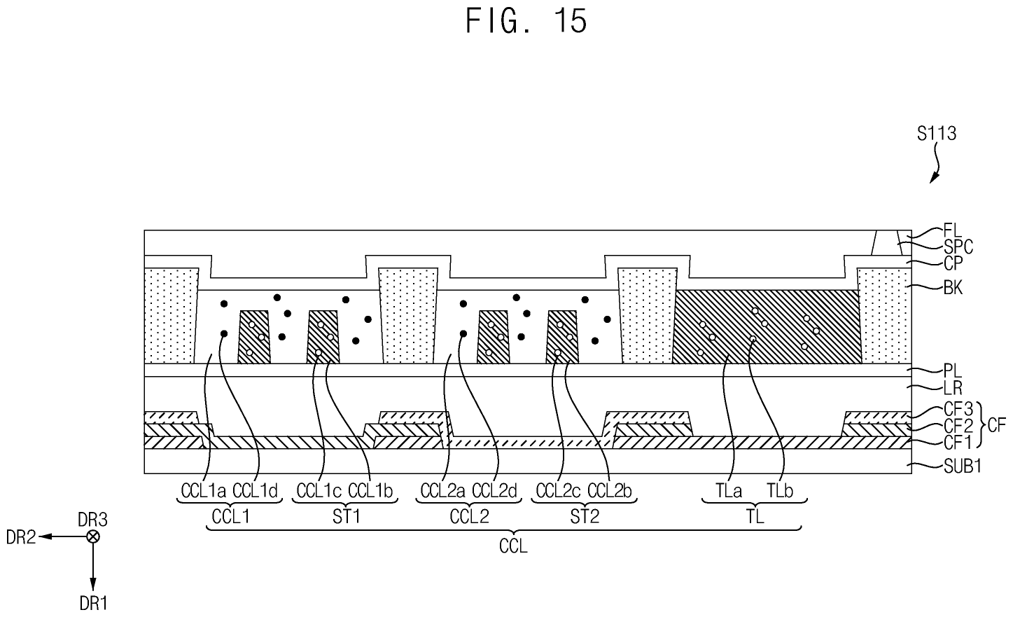

Referring to FIG. 13, the first color conversion part CCL1 covers the first organic structure ST1 and the second color conversion part CCL2 covers the second organic structure ST2. The first color conversion part CCL1 and the second color conversion part CCL2 may be formed in the pixel opening formed in the light-blocking layer BK (S109). Since the first color conversion part CCL1 and the second color conversion part CCL2 have substantially the same structure, the following description will focus on the first color conversion part CCL1.

For example, the first color conversion part CCL1 may be formed by injecting ink mixed with the first color conversion particle CCL1d in the first dispersion part CCL1a into the pixel opening and curing it.

When prepared this way, the first color conversion part CCL1 might not include the scattering particle (e.g., the first scattering particle CCL1c).

Referring to FIGS. 14, 15, and 16, the capping layer CP may be formed on the light-blocking layer BK and the color conversion layer CCL (S111). The spacer SPC may be formed on the capping layer CP (S113). Through this, the color conversion substrate 100 may be formed. Later, it can be combined with the array substrate 200 (S115). At this time, the color conversion substrate 100 and the array substrate 200 may be combined by bonding with the sealing member SLM, and the gap between the color conversion substrate 100 and the array substrate 200 may be filled. To this end, the filling layer FL may be formed between the color conversion substrate 100 and the array substrate 200. Sealing the color conversion substrate 100 and the array substrate 200 so that they are attached forms the display device 10.

However, the disclosure is not limited thereto. For example, the capping layer CP, the spacer SPC, and the filling layer FL may be omitted.

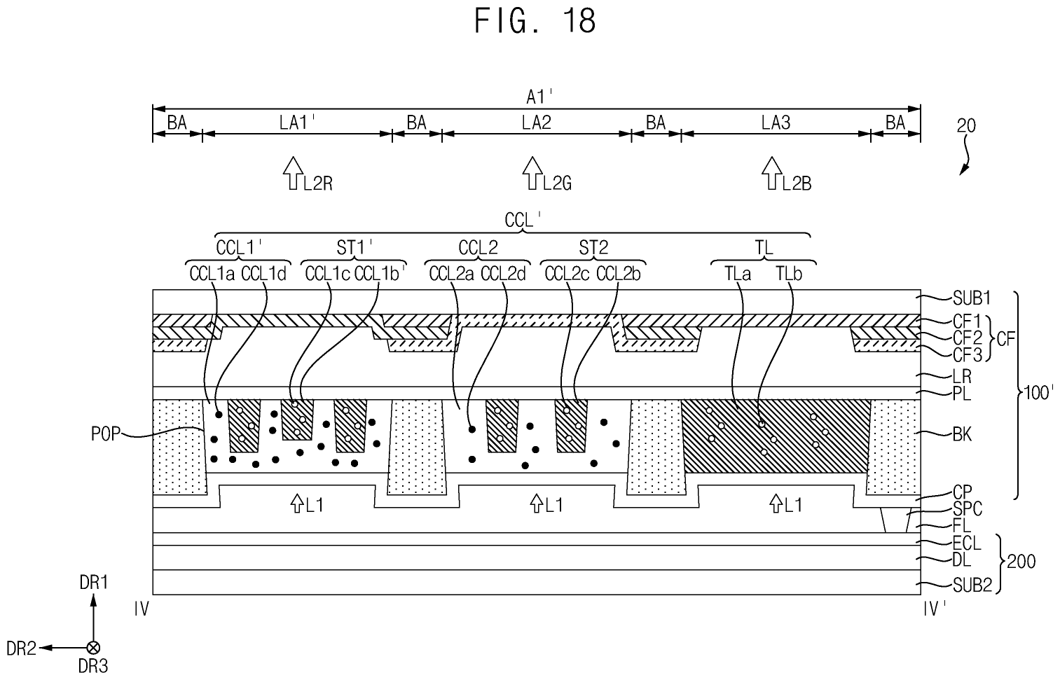

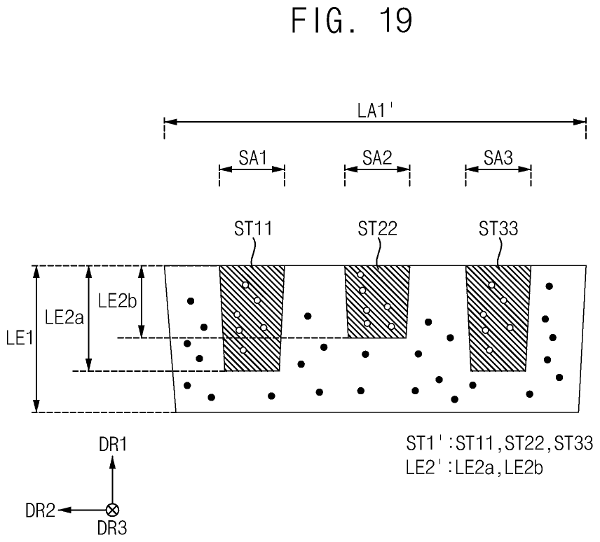

FIG. 17 is an enlarged view illustrating a color conversion substrate. FIG. 18 is a cross-sectional view illustrating the display device including the color conversion substrate of FIG. 17. FIG. 19 is an enlarged view of the first organic structure included in the display device of FIG. 18.

For example, a display device 20 may differ from the display device 10 described above with reference to FIGS. 1, 2, 3, 4, 5, 6, 7, and 8 only in the structure of a color conversion layer CCL′. Therefore, hereinafter, descriptions that overlap with those of the display device 10 described above with reference to FIGS. 1, 2, 3, 4, 5, 6, 7, and 8 will be omitted or abbreviated.

Referring to FIGS. 1, 17, 18, and 19, the display device 20 may include a first area A1′ and the second area A2, and the third area A3 in the plan view, similar to what was described above with reference to FIG. 1.

The second area A2 may surround the first area A1′ in the plan view. The third area A3 may surround the second area A2 in the plan view.

The first area A1′ may be the display area where the image is displayed. The second area A2 and the third area A3 may be the non-display areas where the images are not displayed. Specifically, the second area A2 may be the sealing area. The sealing area may be an area where the sealing member SLM is disposed. The third area A3 may be the outer area. The outer area may be the area where the circuit structures are placed.

The display device 20 may include a color conversion substrate 100′, the sealing member SLM, and the array substrate 200.

The color conversion substrate 100′ and the array substrate 200 may face each other. For example, the color conversion substrate 100′ and the array substrate 200 may face each other in the first direction DR1.

The array substrate 200 may include a plurality of pixels. For example, the plurality of pixels may be arranged in the first area A1′. Each of the plurality of pixels may include the light-emitting device (e.g., the first light-emitting diode LED1, the second light-emitting diode LED2, and the third light-emitting diode LED3 of FIG. 6).

The sealing member SLM may be disposed between the array substrate 200 and the color conversion substrate 100′ in the cross-sectional view. For example, the sealing member SLM may be disposed in the second area A2. Specifically, the sealing member SLM may be disposed to surround the first area A1′ in the second area A2.

The filling layer FL may be disposed between the array substrate 200 and the color

conversion substrate 100′. For example, the filling layer FL may be disposed in the first area A1′ in the plan view.

In an embodiment, the color conversion substrate 100′ may include the first base substrate SUB1, the color filter layer CF, the low refractive layer LR, the protective layer PL, the light-blocking layer BK, the color conversion layer CCL′, the capping layer CP, and the spacer SPC.

For example, the first area A1′ may include the light-emitting area and the light-blocking area BA. Specifically, the light-emitting area may include a first transparent area LA1′, the second transparent area LA2, and the third transparent area LA3. The first transparent area LA1′, the second transparent area LA2, and the third transparent area LA3 may be spaced apart from each other in the plan view and may be repeatedly arranged. However, the disclosure is not limited thereto. The light-emitting area may include two or four or more types of transparent areas.

The incident light L1 that passes through the color conversion substrate 100′ may be emitted outside of the display device 20. In the first transparent area LA1′, the first transmitted light L2R may be emitted as red light. In the second transparent area LA2, the second transmitted light L2G may be emitted as green light. In the third transparent area LA3, the third transmitted light L2B may be emitted as blue light. However, the disclosure is not limited thereto.

The light-blocking area BA may surround the first transparent area LA1′, the second transparent area LA2, and the third transparent area LA3 in the plan view. For example, the light-blocking area BA may have the grid shape in the plan view. However, the disclosure is not limited thereto.

In an embodiment, as the display device 20 includes the first area A1′, the second area A2, and the third area A3, the first base substrate SUB1 may also include the first area A1′, the second area A2, and the third area A3.

In an embodiment, the color filter layer CF may be disposed on the first base substrate SUB1 (e.g., in the negative direction of the first direction DR1).

The color filter layer CF may include the plurality of color filter patterns. For example, the color filter layer CF may include the first color filter pattern CF1, the second color filter pattern CF2, and the third color filter pattern CF3.

Each of the plurality of color filter patterns may overlap the light-emitting area. For example, the first color filter pattern CF1 may overlap the third transparent area LA3. Accordingly, the first color filter pattern CF1 may selectively transmit blue light. The second color filter pattern CF2 may overlap the first transparent area LA1′. Accordingly, the second color filter pattern CF2 may selectively transmit red light. The third color filter pattern CF3 may overlap the second transparent area LA2. Accordingly, the third color filter pattern CF3 may selectively transmit green light. The color filter layer CF may selectively transmit only light of a specific wavelength and emit various colored lights to the outside of the display device 20.

In the light-blocking area BA, the portion of the first color filter pattern CF1, the portion of the second color filter pattern CF2, and the portion of the third color filter pattern CF3 may overlap each other. Accordingly, the color filter layer CF may prevent color mixing from occurring between the adjacent first, second, and third transparent areas LA1′, LA2, and LA3. However, the disclosure is not limited thereto. For example, the color filter layer CF may be disposed only in the first area A1′, and the additional light-blocking member may be disposed in the second area A2 and the third area A3.

The light-blocking layer BK may be disposed in the first area A1′. For example, the light-blocking layer BK may define the light-emitting area. In an embodiment, the light-blocking layer BK may define the first transparent area LA1′, the second transparent area LA2, and the third transparent area LA3. To this end, the light-blocking layer BK might not overlap the light-emitting area (e.g., the first transparent area LA1′, the second transparent area LA2, and the third transparent area LA3), and the light-blocking layer BK may entirely overlap with the light-blocking area BA. For example, the light-blocking layer BK may have the grid shape in the plan view.

A plurality of openings may be defined in the light-blocking layer BK. For example, the pixel opening POP and the dummy opening DOP may be defined in the light-blocking layer BK. The dummy opening DOP may be adjacent to the pixel opening POP.

The color conversion layer CCL′ may be disposed in the pixel opening POP of the light-blocking layer BK in the first area A1′. The color conversion layer CCL′ may convert the color of the incident light L1.

In an embodiment, the color conversion layer CCL′ may include the plurality of color conversion parts spaced apart from each other. For example, the color conversion layer CCL′ may include a first color conversion part CCL1′, the second color conversion part CCL2, and the transparent part TL.

In an embodiment, the color conversion layer CCL′ may include a first organic structure ST1′, a first color conversion part CCL1′, the second organic structure ST2, the second color conversion part CCL2, and the transparent part TL.

In an embodiment, the first organic structure ST1′ may overlap the first transparent area LA1′ and may include the first scattering particle CCL1c and an organic dispersion part CCL1b′. The first scattering particle CCL1c may be dispersed and arranged within the organic dispersion part CCL1b′.

In an embodiment, the organic dispersion part CCL1b′ may include the light-transmitting organic material. The light-transmitting organic material may be the material that may transmit all wavelengths of visible light. For example, the organic material may be the photoresist. In this case, the first organic structure ST1′ may be formed through the photolithography process. However, the disclosure is not limited thereto.

In an embodiment, the first color conversion part CCL1′ may be disposed in the first transparent area LA1′ and may include the first color conversion particle CCL1d and the first dispersion part CCL1a. The first color conversion particle CCL1d may be dispersed in the first dispersion part CCL1a.

The first color conversion part CCL1′ may convert the incident light L1 into the red first transmitted light L2R. The incident light L1 that is not converted by the first color conversion part CCL1′ may be blocked (e.g., absorbed or reflected) by the second color filter pattern CF2. Accordingly, in the first transparent area LA1′, the red first transmitted light L2R passes through the first base substrate SUB1 and be emitted to the outside of the display device 20.

In an embodiment, the first color conversion part CCL1′ may cover the first organic structure ST1′. To this end, the first organic structure ST1′ may be first formed in the pixel opening POP overlapping the first transparent area LA1′ and defined by the light-blocking layer BK, and then the first color conversion part CCL1′ may be formed to cover the first organic structure ST1′.

As shown in FIG. 19, in an embodiment, the first color conversion part CCL1′ may have the first height LE1 and the first organic structure ST1′ may have the second height LE2. The first height LE1 may be greater than the second height LE2a, LE2b.

In an embodiment, the first scattering particle CCL1c may be disposed only in the first organic structure ST1′, and the first color conversion particle CCL1d may be disposed only in the first dispersion part CCL1a. In other words, the first scattering particle CCL1c might not be disposed in the first dispersion part CCL1a.

To this end, the first organic structure ST1′ may be formed of the organic dispersion part CCL1b′ including the first scattering particle CCL1c using the photolithography process. The first color conversion part CCL1′ may be formed of the first dispersion part CCL1a including the first color conversion particle CCL1d using the inkjet process.

In other words, as the display device 20 includes the first organic structure ST1′, the space in which the first scattering particle CCL1c is disposed may be limited (or reduced).

In an embodiment, the first organic structure ST1′ may include a plurality of sub-organic structures. For example, the first organic structure ST1′ may include a first sub-organic structure ST11, a second sub-organic structure ST22, and a third organic structure ST33. The first sub-organic structure ST11 may be located in the first arrangement area SA1, the second sub-organic structure ST22 may be located in the second arrangement area SA2, and the third organic structure ST33 may be located in a third arrangement area SA3. Accordingly, the space in which the first scattering particle CCL1c is disposed may be limited to the first arrangement area SA1, the second arrangement area SA2, and the third arrangement area SA3.

In an embodiment, the plurality of sub-organic structures may have different heights. For example, the first sub-organic structure ST11 and the third sub-organic structure ST33 may be relatively closer to the light-blocking layer BK than the second sub-organic structure ST22. In this case, a height LE2a of the first sub-organic structure ST11 and the third sub-organic structure ST33 may be greater than a height LE2b of the second sub-organic structure ST22. Accordingly, the probability of reaction between the incident light L1 and the first color conversion particle CCL1d may be increased, thereby increasing light efficiency. Additionally, the optical path of the incident light L1 may be diversified.

In FIG. 19, the height of the sub-organic structures that are closer to the light-blocking layer BK is shown to be greater than the height of the sub-organic structures that are closer to the center area of the first transparent area LA1′. For example, in the embodiment of FIG. 19, a peripheral second height LE2a is greater than a central second height LE2b. However, the disclosure is not limited thereto. In another embodiment, as shown in FIG. 5, the height of all the organic structures (ST11, ST22, and ST33 in the embodiment of FIG. 19) may be the same. Alternatively, the height of the organic structures ST11, ST22, and ST33 may all be different.

In an embodiment, the organic dispersion layer TLa may include the same material as the organic dispersion part CCL1b′ included in the first organic structure ST1′. For example, the organic dispersion layer TLa included in the transparent part TL may include the light-transmitting organic material. In this case, the first organic structure ST1′, the second organic structure ST2, and the transparent part TL may be formed simultaneously using the same process. Accordingly, in an embodiment, the height of the first organic structure ST1′ and the transparent part TL may be the same.

The array substrate 200 may include the second base substrate SUB2, the display device layer DL, and the encapsulation layer ECL.

In an embodiment, the second base substrate SUB2 may face the first base substrate SUB1. The display device layer DL may be disposed on the second base substrate SUB2. The display device layer DL may include the buffer layer BFR, the first to third transistors TR1, TR2, and TR3, the insulating layer IL, the pixel defining layer PDL, and the first to third light-emitting diodes LED1, LED2, and LED3. The buffer layer BFR may be disposed on the second base substrate SUB2. The first to third transistors TR1, TR2, and TR3 may be disposed in the first area A1′ on the buffer layer BFR. The insulating layer IL may cover the first to third transistors TR1, TR2, and TR3. The first to third light-emitting diodes LED1, LED2, and LED3 may be disposed on the insulating layer IL. The pixel defining layer PDL may be disposed on the first to third pixel electrodes AE1, AE2, and AE3. The pixel defining layer PDL may define the pixel opening exposing at least the portion of each of the first to third pixel electrodes AE1, AE2, and AE3. The light-emitting layer EL may be disposed on the first to third pixel electrodes AE1, AE2, and AE3 exposed by the pixel opening of the pixel defining layer PDL. The common electrode CE may be disposed on the light-emitting layer EL. In an embodiment, the common electrode CE may extend continuously on the first area A1′ across the plurality of pixels. The first pixel electrode AE1, the light-emitting layer EL, and the common electrode CE may constitute the first light-emitting diode LED1, the second pixel electrode AE2, the light-emitting layer EL, and the common electrode CE may constitute the second light-emitting diode LED2, and the third pixel electrode AE3, the light-emitting layer EL, and the common electrode CE may constitute the third light-emitting diode LED3. The encapsulation layer ECL may be disposed on the display device layer DL.

The filling layer FL may maintain the distance between the color conversion substrate 100′ and the array substrate 200. In an embodiment, the filling layer FL may be disposed between the capping layer CP and the encapsulation layer ECL. For example, when the capping layer CP is omitted, the filling layer FL may be disposed between the light-blocking layer BK, the first color conversion part CCL1′, the second color conversion part CCL2, the transparent part TL, and the encapsulation layers ECL. For example, when the encapsulation layer ECL is omitted, the filling layer FL may be disposed between the capping layer CP and the display device layer DL.

As the display device 20 includes the plurality of sub-organic structures having different heights, the optical path of the incident light L1 may vary in various ways. Accordingly, the light efficiency may increase.

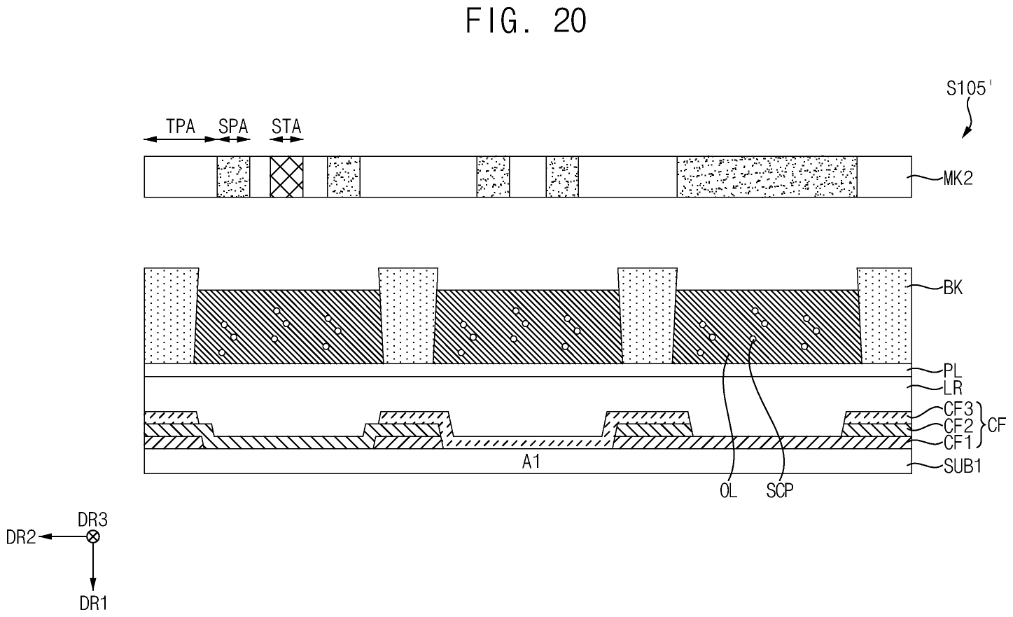

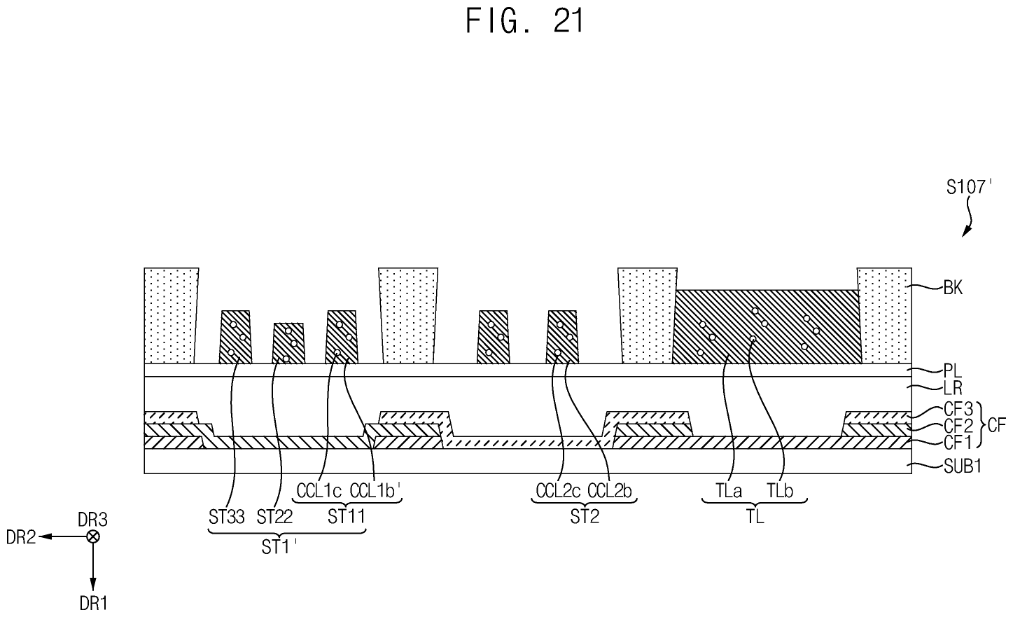

FIGS. 20, 21, 22, and 23 are views illustrating a manufacturing method of the display device of FIG. 18.

Hereinafter, descriptions of structures that are similar with the display device 10 described above with reference to FIGS. 1 to 8, the manufacturing method of the display device 10 described above with reference to FIGS. 9 to 16, and the display device 20 described above with reference to FIGS. 17 to 19 will be omitted or abbreviated.

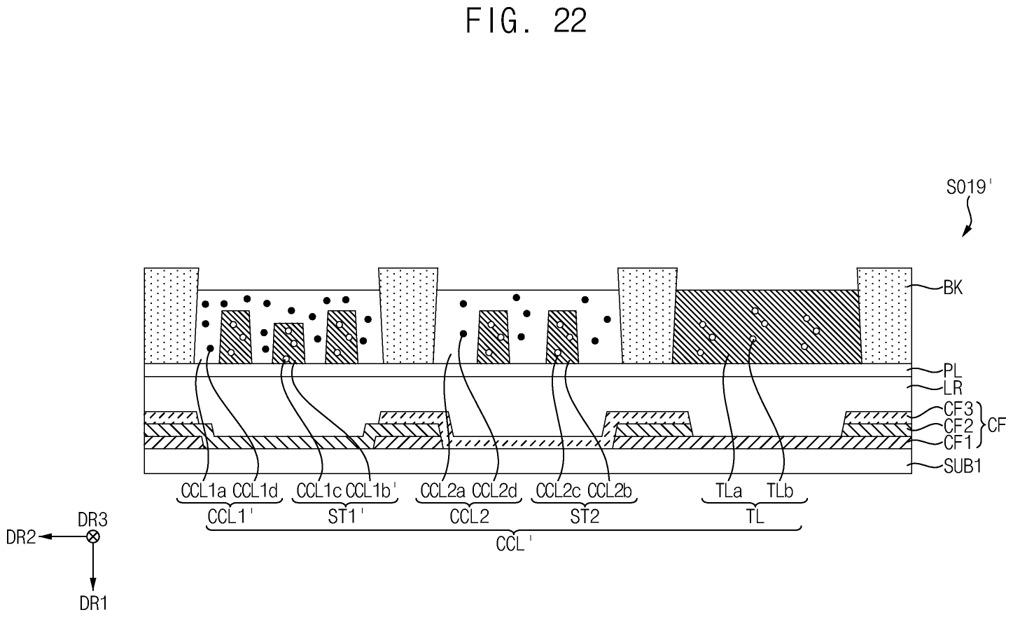

Referring to FIGS. 20 and 21, the color filter layer CF may be formed on the first base substrate SUB1, the low refractive layer LR, the protective layer PL, and the light-blocking layer BK may be formed on the color filter layer CF sequentially. The organic material OL including the scattering particle SCP may be formed in the pixel opening formed in the light-blocking layer BK, and a mask MK2 may be disposed (S105′). Next, the first organic structure ST1′, the second organic structure ST2, and the transparent part TL may be formed through the exposure and development process (S107′).

For example, the organic material OL may be the photoresist. At this time, the scattering particle SCP may be mixed with the organic material OL and injected into the pixel opening. Here, the scattering particle SCP may correspond to the first scattering particle CCL1c, the second scattering particle CCL2c, and/or the third scattering particle TLb of FIG. 18.

For example, the mask MK2 may include the light transmitting part TPA, a semi-transmitting part STA, and the light-blocking part SPA. The light transmitting part TPA may be a part with a highest light transmittance, the light-blocking part SPA may be a part with a lowest light transmittance (i.e., the light-blocking part SPA does not transmit light), and the semi-transmitting part STA may be a part with a transmittance greater than the light-blocking part SPA and smaller than the light transmittance of the semi-transmitting part STA.

In an embodiment, the mask MK2 may be placed so that the light-blocking part SPA is formed at a location where the organic structures (e.g., the first organic structure ST1′ and the second organic structure ST2) and the transparent part TL are to be formed.

In an embodiment, the organic structures may be formed to have different heights. For example, the height of the second sub-organic structure ST22 may be smaller than that of the first sub-organic structure ST11 and the third sub-organic structure ST33. In this case, the mask MK2 may be placed so that the light-blocking part SPA is located at a location where the first sub-organic structure ST11 and the third sub-organic structure ST33 are to be formed, and the semi-transmitting part STA is located at a location where the second sub-organic structure ST22 is to be formed.

The photoresist may be used as either a negative type or a positive type. The mask MK2 may be a half-tone mask including areas with various light transmittance.

The organic structure may be formed in various ways and with various materials.

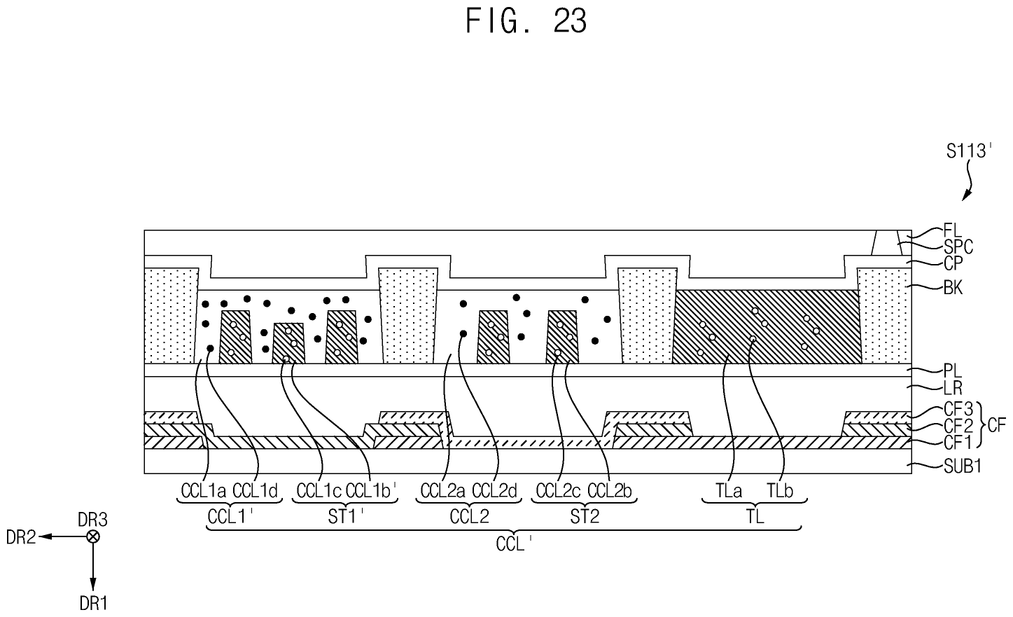

Referring to FIG. 22, the first color conversion part CCL1′ that covers the first organic structure ST1′ and the second color conversion part CCL2 that covers the second organic structure ST2 may be formed in the pixel opening formed in the light-blocking layer BK (S109′). Since the first color conversion part CCL1′ and the second color conversion part CCL2 have substantially the same structure, the following description will focus on the first color conversion part CCL1′.

For example, the first color conversion part CCL1′ may be formed by injecting ink that is mixed with the first color conversion particle CCL1d in the first dispersion part CCL1a into the pixel opening and curing it.

Through this process, the first color conversion part CCL1′ might not include the scattering particle (e.g., the first scattering particle CCL1c).

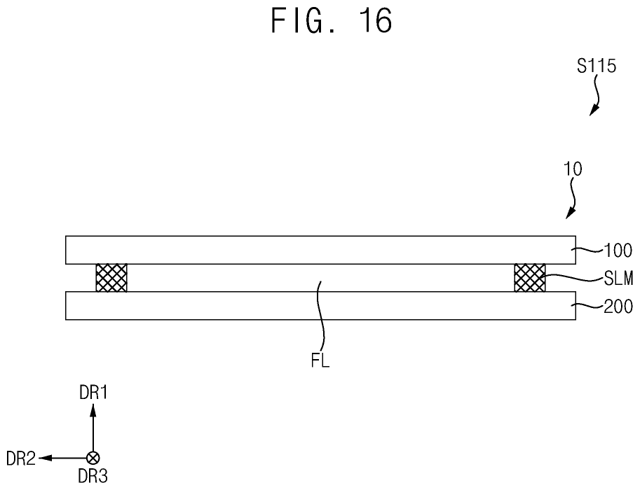

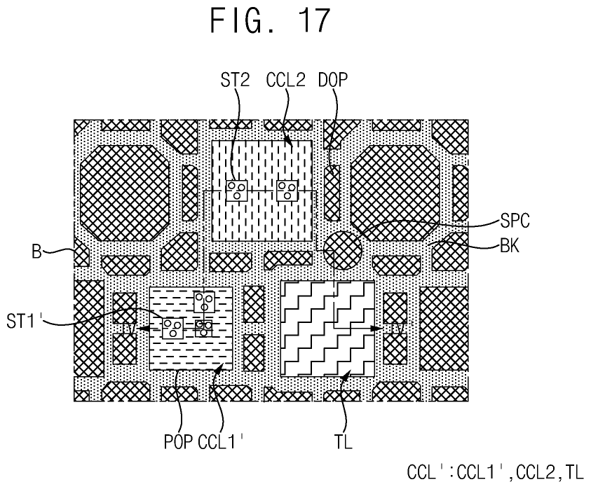

Referring to FIGS. 16, 18, and 23, the capping layer CP may be formed on the light-blocking layer BK and the color conversion layer CCL′. The spacer SPC may be formed on the capping layer CP (S113′). Through this process, the color conversion substrate 100′ may be formed. Afterwards, it may be bonded to the array substrate 200. Similar to what was described above in FIG. 16, the color conversion substrate 100′ and the array substrate 200 may be bonded by the sealing member SLM, the filling layer FL may be formed between the color conversion substrate 100′ and the array substrate 200 to fill the gap between the color conversion substrate 100′ and the array substrate 200. Through this process, the display device 20 may be formed.

However, the disclosure is not limited thereto. For example, the capping layer CP, the spacer SPC, and the filling layer FL may be omitted.

In the above, as shown in FIG. 23, there is a plurality of first organic structures ST1′ covered by the first color conversion part CCL1′ and having different heights. However, the disclosure is not limited thereto. For example, there may be a plurality of second organic structures ST2 having different heights. Alternatively, there may be a plurality of first organic structures ST1′ having different heights and a plurality of the second organic structures ST2 having different heights.

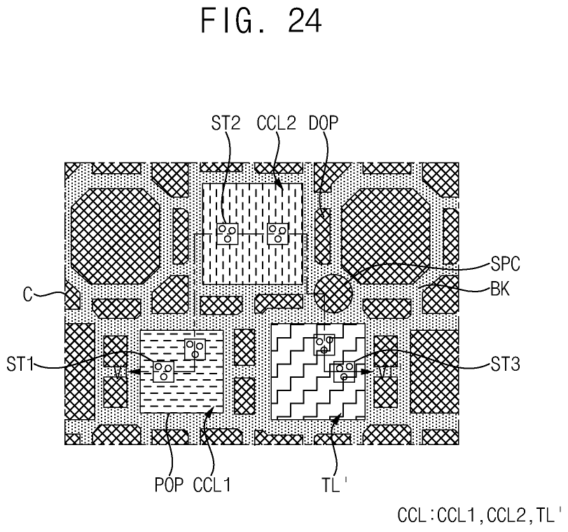

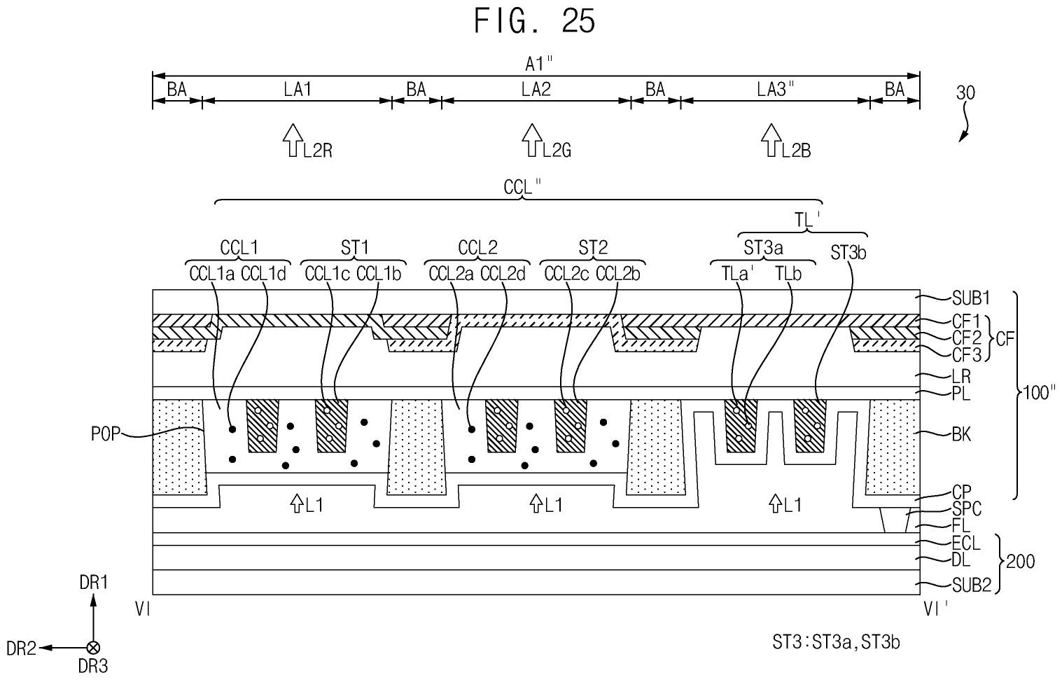

FIG. 24 is an enlarged view illustrating a color conversion substrate. FIGS. 25 is a view illustrating a display device including the color conversion substrate of FIG. 24.

The display device 30 of FIG. 25 may be different from the display device 10 of FIGS. 1 to 8 and the display device 20 of FIGS. 17 to 19 primarily in the structure of the color conversion layer CCL″. Therefore, hereinafter, overlapping descriptions of the display device described above with reference to FIGS. 1 to 8 and the display device 20 described above with reference to FIGS. 17 to 19 will be omitted or abbreviated.

Referring to FIGS. 1, 24, and 25, the display device 30 may include a first area A1″, the second area A2, and the third area A3 in the plan view.

The second area A2 may surround the first area A1″ in the plan view. The third area A3 may surround the second area A2 in the plan view.

The first area A1″ may be the display area where the image is displayed. The second area A2 and the third area A3 may be the non-display areas where the images are not displayed. Specifically, the second area A2 may be the sealing area. The sealing area may be an area where the sealing member SLM is disposed. The third area A3 may be the outer area. The outer area may be the area where the circuit structures are placed.

The display device 30 may include a color conversion substrate 100″, the sealing member SLM (see FIG. 2), and the array substrate 200.

The color conversion substrate 100″ and the array substrate 200 may face each other. For example, the color conversion substrate 100″ and the array substrate 200 may face each other in the first direction DR1.

The array substrate 200 may include a plurality of pixels. For example, the plurality of pixels may be arranged in the first area A1″. Each of the plurality of pixels may include the light-emitting device (e.g., the first light-emitting diode LED1, the second light-emitting diode LED2, and the third light-emitting diode LED3 of FIG. 6).

The sealing member SLM may be disposed between the array substrate 200 and the color conversion substrate 100″ in the cross-sectional view. For example, the sealing member SLM may be disposed in the second area A2. Specifically, the sealing member SLM may be disposed to surround the first area A1″ in the second area A2.

The filling layer FL may be disposed between the array substrate 200 and the color conversion substrate 100″. For example, the filling layer FL may be disposed in the first area A1″ in the plan view.

In an embodiment, the color conversion substrate 100″ may include the first base substrate SUB1, the color filter layer CF, the low refractive layer LR, the protective layer PL, the light-blocking layer BK, the color conversion layer CCL″, the capping layer CP, and the spacer SPC.

For example, the first area A1″ may include the light-emitting area and the light-blocking area BA. Specifically, the light-emitting area may include the first transparent area LA1, the second transparent area LA2, and a third transparent area LA3′. The first transparent area LA1, the second transparent area LA2, and the third transparent area LA3′ may be spaced apart from each other in the plan view and may be repeatedly arranged. However, the disclosure is not limited thereto. The light-emitting area may include two or four or more types of transparent areas.

The incident light L1 that passes through the color conversion substrate 100″ may be emitted to the outside of the display device 30. In the first transparent area LA1, the first transmitted light L2R may be emitted as red light. In the second transparent area LA2, the second transmitted light L2G may be emitted as green light. In the third transparent area LA3′, the third transmitted light L2B may be emitted as blue light. However, the disclosure is not limited thereto.

The light-blocking area BA may surround the first transparent area LA1, the second transparent area LA2, and the third transparent area LA3′ in the plan view. For example, the light-blocking area BA may have the grid shape in the plan view. However, the disclosure is not limited thereto.

In an embodiment, as the display device 30 includes the first area A1″, the second area A2, and the third area A3, the first base substrate SUB1 may also include the first area A1″, the second area A2, and the third area A3.

In an embodiment, the color filter layer CF may be disposed on the first base substrate SUB1 (e.g., in the direction opposite to the first direction DR1).

The color filter layer CF may include the plurality of color filter patterns. For example, the color filter layer CF may include the first color filter pattern CF1, the second color filter pattern CF2, and the third color filter pattern CF3.

Each of the plurality of color filter patterns may overlap the light-emitting area. For example, the first color filter pattern CF1 may overlap the third transparent area LA3′. Accordingly, the first color filter pattern CF1 may selectively transmit the blue light. The second color filter pattern CF2 is in the first transparent area LA1. Accordingly, the second color filter pattern CF2 may selectively transmit red light. The third color filter pattern CF3 is in the second transparent area LA2. Accordingly, the third color filter pattern CF3 may selectively transmit green light. The color filter layer CF may selectively transmit only light of a specific wavelength and emit various colored lights to the outside of the display device 30.

In the light-blocking area BA, the portion of the first color filter pattern CF1, the portion of the second color filter pattern CF2, and the portion of the third color filter pattern CF3 may overlap each other. Accordingly, the color filter layer CF may prevent color mixing from occurring between the adjacent first, second, and third transparent areas LA1, LA2, and LA3′. However, the disclosure is not limited thereto. For example, the color filter layer CF may be disposed only in the first area A1″, and the additional light-blocking member may be disposed in the second area A2 and the third area A3.

The light-blocking layer BK may be disposed in the first area A1″. For example, the light-blocking layer BK may define the light-emitting area. In an embodiment, the light-blocking layer BK may define the boundaries of first transparent area LA1, the second transparent area LA2, and the third transparent area LA3′. To this end, the light-blocking layer BK might not overlap the light-emitting area (e.g., the first transparent area LA1, the second transparent area LA2, and the third transparent area LA3′), and the light-blocking layer BK defines the light-blocking area BA. In some embodiments, the light-blocking layer BK may have the grid shape in the plan view.

A plurality of openings may be defined in the light-blocking layer BK. For example, the pixel opening POP and the dummy opening DOP may be defined in the light-blocking layer BK. The dummy opening DOP may be adjacent to the pixel opening POP.

The color conversion layer CCL″ may be disposed in the pixel opening POP of the light-blocking layer BK in the first area A1″. The color conversion layer CCL″ may convert the color of the incident light L1.

In an embodiment, the color conversion layer CCL″ may include the plurality of color conversion parts spaced apart from each other. For example, the color conversion layer CCL″ may include a first color conversion part CCL1, the second color conversion part CCL2, and a transparent part TL′.

In an embodiment, the color conversion layer CCL″ may include the first organic structure ST1, the first color conversion part CCL1, the second organic structure ST2, the second color conversion part CCL2, and the transparent part TL′.

In an embodiment, the transparent part TL′ may include a plurality of sub-organic structures. For example, the transparent part TL′ may include a first sub-organic structure ST3aand a second sub-organic structure ST3b. Accordingly, a space in which the third scattering particle TLb is disposed may be limited.

In an embodiment, the plurality of sub-organic structures may have different heights. Accordingly, the optical path of the incident light L1 may be diversified.

In another embodiment, the plurality of sub-organic structures may have the same height. For example, the height of the plurality of sub-organic structures may be the same as the height of the first organic structure ST1 and the second organic structure ST2. In this case, the first organic structure ST1, the second organic structure ST2, and the plurality of sub-organic structures may be formed simultaneously. (e.g., the first organic structure ST1, the second organic structure ST2, and the plurality of sub-organic structures may be formed with one mask). To this end, the first organic structure ST1, the second organic structure ST2, and the transparent part TL′ may include the same material. there is. For example, the transmitting part TL′ may include a light-transmitting organic material.

The array substrate 200 may include the second base substrate SUB2, the display device layer DL, and the encapsulation layer ECL.

The filling layer FL may maintain the gap between the color conversion substrate 100″ and the array substrate 200. In an embodiment, the filling layer FL may be disposed between the light-blocking layer BK, the first color conversion part CCL1, the second color conversion part CCL2, the transparent part TL′, and the display device layer DL.

As the display device 30 of the disclosure includes the transparent part TL′ including the plurality of sub-organic structures (e.g., the first sub-organic structure ST3a and the second sub-organic structure ST3b), the display quality of the black color may be improved by reducing the area where the external light is reflected in the light-emitting area.

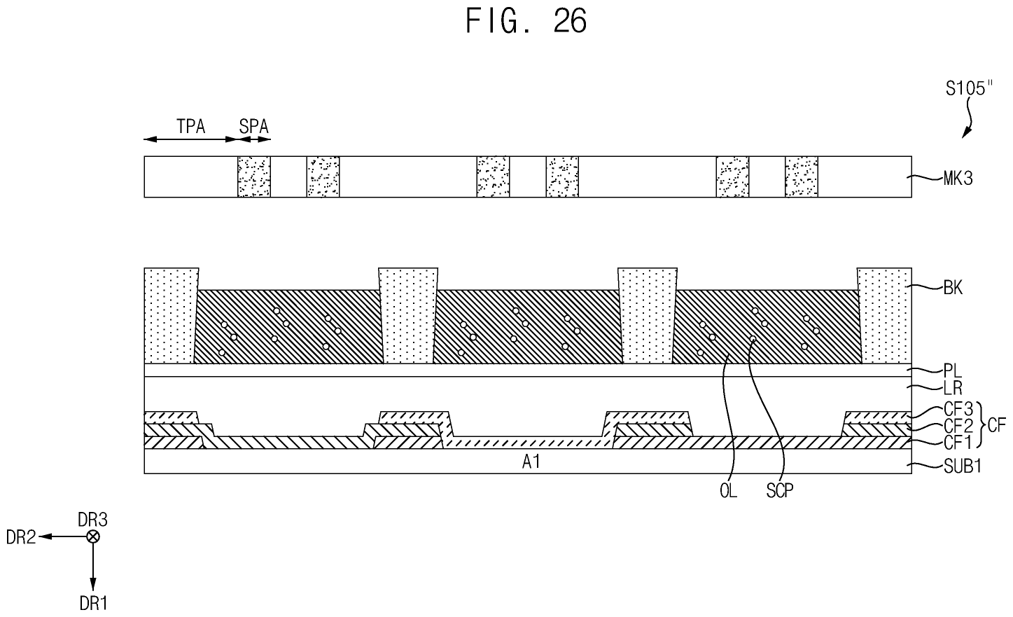

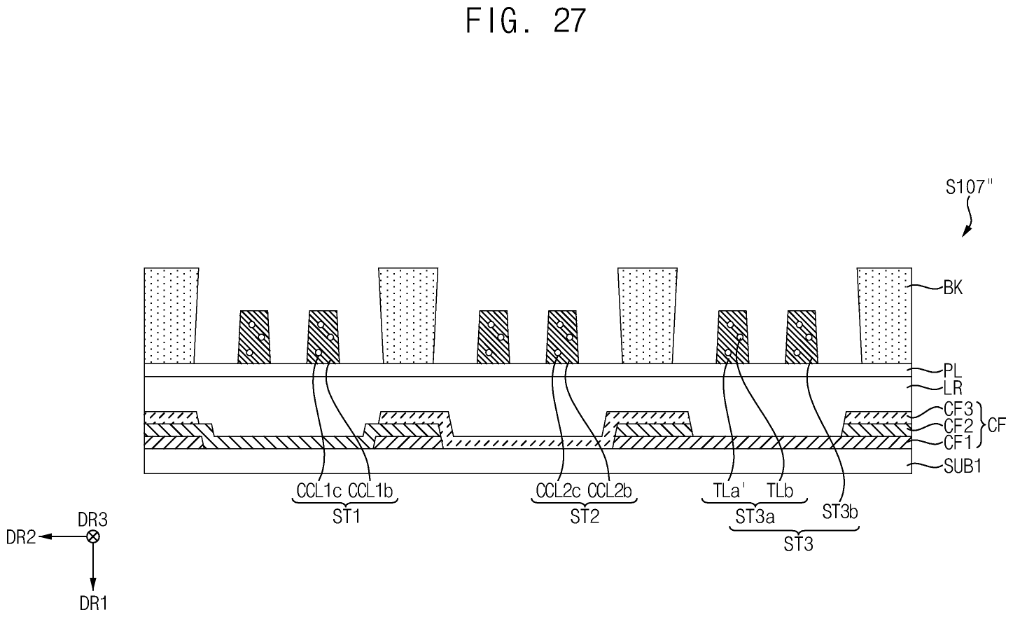

FIGS. 26, 27, 28, and 29 are views illustrating a manufacturing method of the display device of FIG. 25.

Hereinafter, descriptions that overlap with the description of the display device 10 that is described above with reference to FIGS. 1, 2, 3, 4, 5, 6, 7, and 8, the manufacturing method of the display device 10 that is described above with reference to FIGS. 9, 10, 11, 12, 13, 14, 15, and 16, the display device 20 that is described above with reference to FIGS. 17, 18, and 19, and the manufacturing method of the display device 20 that is described above with reference to FIGS. 20, 21, 22, and 23 will be omitted or abbreviated.

Referring to FIGS. 26 and 27, the color filter layer CF, the low refractive layer LR, the protective layer PL, and the light-blocking layer BK may be sequentially formed on the first base substrate SUB1. The organic material OL including the scattering particle SCP may be formed in the pixel opening formed in the light-blocking layer BK, and a mask MK3 may be disposed (S105″). Next, through exposure and development processes, the transparent part TL′ including the first organic structure ST1, the second organic structure ST2, and the plurality of sub-organic structures may be formed (S107′). For example, the transparent part TL′ may include the first sub-organic structure ST3a and the second sub-organic structure ST3b.

For example, the organic material OL may be the photoresist. At this time, the scattering particle SCP may be mixed with the organic material OL and injected into the pixel opening. Here, the scattering particle SCP may correspond to the first scattering particle CCL1c, the second scattering particle CCL2c, and/or the third scattering particle TLb of FIG. 25.

For example, the mask MK3 may include the light transmitting part TPA and the light-blocking part SPA. The light transmitting part TPA may be a part with a highest light transmittance, and the light-blocking part SPA may be the part with a lowest light transmittance (i.e., the light-blocking part SPA does not transmit light).

In an embodiment, the mask MK3 may be placed so that the light-blocking part SPA is formed at a location where the organic structures (e.g., the first organic structure ST1 and the second organic structure ST2) and the plurality of sub-organic structures are to be formed.

However, the disclosure is not limited thereto. The photoresist may be used as either a negative type or a positive type. The mask MK3 may be a half-tone mask including areas with various light transmittance. Accordingly, the transparent part TL′ may include the plurality of sub-organic structures having a height smaller than the height of the light-blocking layer BK.

However, the disclosure is not limited thereto. The organic structure may be formed in various ways and with various materials.

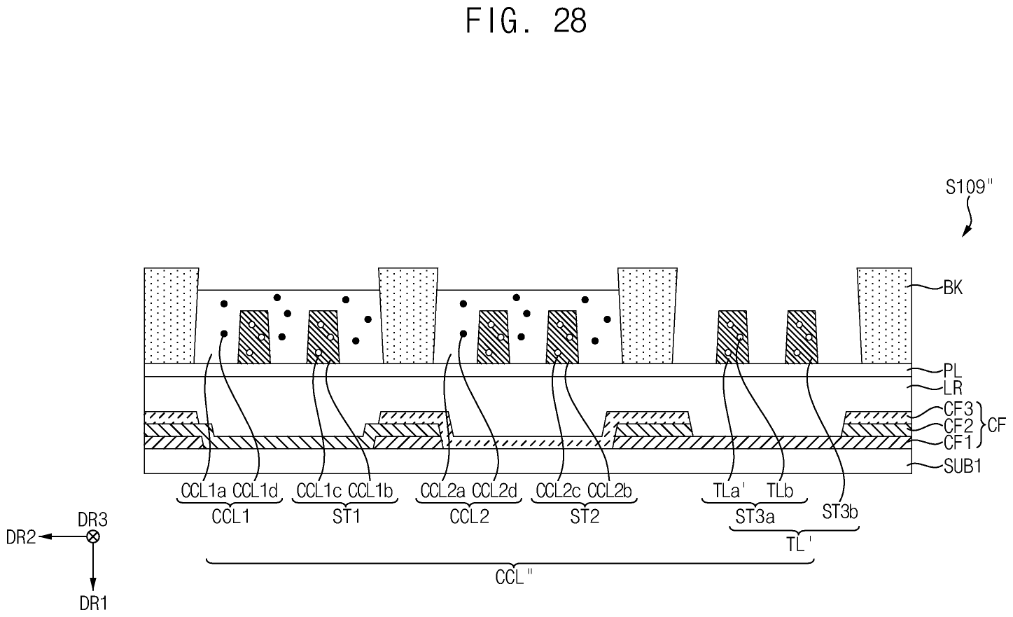

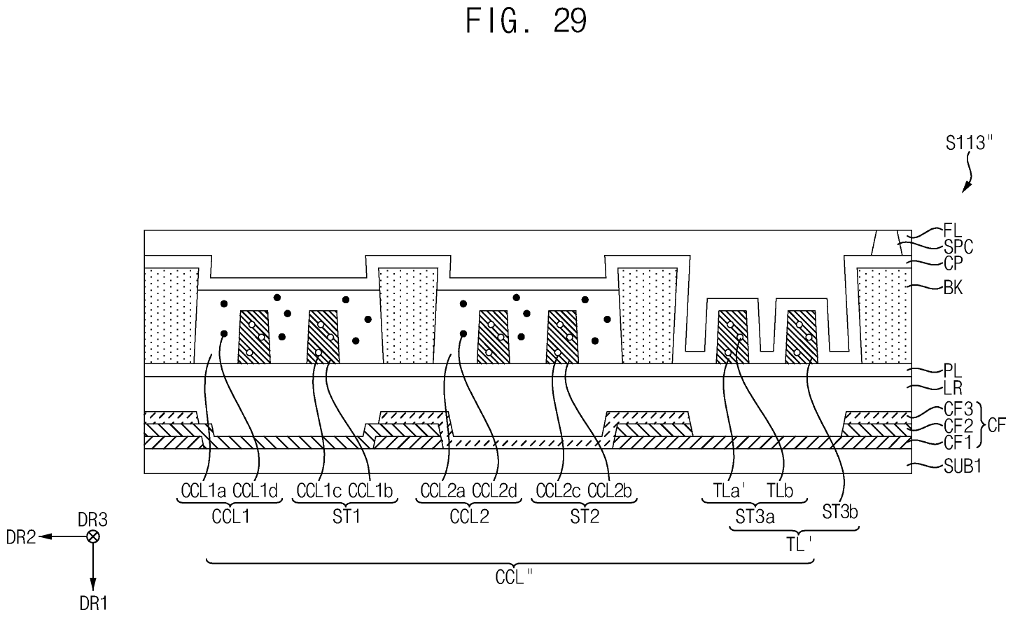

Referring to FIG. 28, the first color conversion part CCL1 covers the first organic structure ST1 and the second color conversion part CCL2 covers the second organic structure ST2 may be formed in the pixel opening formed in the light-blocking layer BK (S109″). The process of forming the color conversion layer CCL″ is the same as described above.

Referring to FIGS. 16, 25, and 29, the capping layer CP may be formed on the light-blocking layer BK and the color conversion layer CCL″. The spacer SPC may be formed on the capping layer CP (S113″). Through this process, the color conversion substrate 100″ may be formed. Similar to what was described above in FIG. 16, the color conversion substrate 100″ may be bonded to the array substrate 200 by the sealing member SLM, the filling layer FL may be formed between the color conversion substrate 100″ and the array substrate 200 to fill the gap between the color conversion substrate 100″ and the array substrate 200. Through this process, the display device 30 may be formed.

However, the disclosure is not limited thereto. For example, one or more of the capping layer CP, the spacer SPC, and the filling layer FL may be omitted.

In FIG. 29, it has been described that a transparent part TL″ includes two sub-organic structures having the same height. However, the disclosure is not limited thereto. For example, the number of the plurality of sub-organic structures may be changed in various ways.

The color conversion substrate and the display device including the color conversion substrate according to embodiments of the disclosure may be applied to a computer, a notebook, a cell phone, a smart phone, a smart pad, a PMP, a PDA, a MP3 player, and the like.

Although the display device and the method of manufacturing the same according to the embodiments have been described with reference to the drawings, the illustrated embodiments are examples, and may be modified and changed by a person having ordinary knowledge in the relevant technical field without departing from the technical spirit described in the following claims.

What is claimed is:

1. A color conversion substrate comprising:
a substrate including a first transparent area and a second transparent area;
a color filter layer disposed on the substrate;
a light-blocking layer disposed on the color filter layer and defining the first transparent area and the second transparent area;
a first organic structure in the first transparent area and including a scattering particle;
a first color conversion part in the first transparent area covering the first organic structure, the first color conversion part including a first color conversion particle; and
a transparent part in the second transparent area and including the scattering particle.

2. The color conversion substrate of claim 1, wherein the scattering particle is absent in the first color conversion layer.

3. The color conversion substrate of claim 1, wherein,
the first color conversion layer has a first height, and
the first organic structure has a second height that is different from the first height.

4. The color conversion substrate of claim 3, wherein the first height is greater than the second height.

5. The color conversion substrate of claim 1, wherein the height of the transparent part is equal to the height of the first organic structure.

6. The color conversion substrate of claim 1, wherein the first organic structure is one of a plurality of first organic structures in the first transparent area, the plurality of first organic structures having a same height.

7. The color conversion substrate of claim 1, wherein the first organic structure is one of a plurality of first organic structures in the first transparent area, the first organic structures having different heights.

8. The color conversion substrate of claim 1, wherein the transparent part is one of a plurality of transparent parts in the second transparent area, the transparent parts having a height smaller than a height of the light-blocking layer.

9. The color conversion substrate of claim 1, wherein the transparent part includes a same material as the first organic structure.

10. The color conversion substrate of claim 9, wherein the transparent part and the first organic structure includes a light-transmitting organic material.

11. A display device comprising:
a first base substrate including a first transparent area and a second transparent area;
a color filter layer disposed on the first base substrate;
a light-blocking layer disposed on the color filter layer and defining the first transparent area and the second transparent area;
a first organic structure in the first transparent area and including a scattering particle;
a first color conversion part in the first transparent area covering the first organic structure, the first color conversion part including a first color conversion particle;
a transparent part in the second transparent area and including the scattering particle;
a second base substrate coupled to the first base substrate;
a display device layer disposed on the second base substrate; and
a filling layer disposed between the display device layer and the light-blocking layer.

12. The display device of claim 11, wherein the scattering particle is absent in the first color conversion layer.

13. The display device of claim 11, wherein,
the first color conversion layer has a first height, and
the first organic structure has a second height that is different from the first height.

14. The display device of claim 13, wherein the first height is greater than the second height.

15. The display device of claim 13, wherein the transparent part has the second height.

16. The display device of claim 11, wherein the first organic structure is one of a plurality of first organic structures in the first transparent area that have the same height.

17. The display device of claim 11, wherein the first organic structure is one of a plurality of first organic structures in the first transparent area, the plurality of organic structures having different heights.

18. The display device of claim 11, wherein the transparent part is one of a plurality of transparent parts that have a height smaller than a height of the light-blocking layer.

19. The display device of claim 11, wherein the transparent part includes a same material as the first organic structure.

20. The display device of claim 19, wherein the transparent part and the first organic structure includes a light-transmitting organic material.
